(19) United States
(12) Patent Application Publication
(10) Pub. No.: US 2026/0056877 A1
(43) Pub. Date: Feb. 26, 2026

(54) MEMORY SYSTEM AND METHOD

(71) Applicant: Kioxia Corporation, Tokyo (JP)

(72) Inventors: Akihiko SAKAI, Fujisawa Kanagawa (JP); Yuji NAGAI, Sagamihara Kanagawa (JP)

(21) Appl. No.: 19/062,809

(22) Filed: Feb. 25, 2025

(30) Foreign Application Priority Data
Aug. 26, 2024 (JP) 2024-144270

(51) Int. Cl. G06F 12/02

(52) U.S. Cl. CPC G06F 12/0246; G06F 2212/7201

(57) ABSTRACT

A memory system includes a nonvolatile memory including first, second, and third arrays of memory cells and a memory controller. The memory controller is configured to perform a two-step program operation of a first type on the first and second arrays. The first type includes a first program operation to set a threshold voltage of the memory cell to be in one of a first plurality of ranges, and then a second program operation to set the threshold voltage to be in one of a second plurality of ranges. The memory controller is configured to perform a two-step program operation of a second type on the third array. The second type includes a third program operation to set a threshold voltage corresponding to partial bits of the multi-bit data, and then a fourth program operation to set a threshold voltage corresponding to the entire bits of the multi-bit data.

### CROSS-REFERENCE TO RELATED APPLICATION

This application is based upon and claims the benefit of priority from Japanese Patent Application No. 2024-144270, filed Aug. 26, 2024, the entire contents of which are incorporated herein by reference.

### FIELD

Embodiments described herein relate generally to a memory system and a method.

### BACKGROUND

In recent years, memory systems including nonvolatile memories are widely spread. As one of such memory systems including semiconductor storage devices, a solid state drive (SSD) including a NAND flash memory is known.

Semiconductor storage devices such as NAND flash memories include a plurality of memory cells each storing data. Controllers of SSDs execute two-step program operations to write data on the plurality of memory cells.

When the two-step program operations are executed, the controllers temporarily store data to be written until the program operation of the second step are executed. Therefore, the controllers require resources for temporarily storing the data to be written. The controllers are required to prevent the temporarily stored data to be written from being lost when abnormal shutdown occurs. Therefore, the controllers execute power loss protection (PLP) to write the data to be written into the NAND flash memories.

As a result, capacities required for the memory systems increase according to an amount of data required to be stored to execute the two-step program operations. Accordingly, techniques capable of reducing the amount of data required to be stored are necessary.

### BRIEF DESCRIPTION OF THE DRAWINGS

FIG. 1 is a block diagram illustrating a configuration example of a memory system according to an embodiment;

FIG. 2 is a block diagram illustrating a configuration example of a NAND chip;

FIG. 3 is a diagram illustrating a configuration example of a memory cell array;

FIG. 4 is a diagram illustrating a configuration example of each of a plurality of blocks in the memory cell array;

FIG. 5 is a diagram illustrating a configuration example of a circuit of the memory cell array;

FIG. 6 is a cross-sectional diagram illustrating a configuration of a string;

FIG. 7 is a cross-sectional diagram illustrating a memory cell along a line VI-VI of FIG. 6;

FIG. 8 is a diagram schematically illustrating a threshold voltage distribution of the memory cell array;

FIG. 9 is a diagram illustrating a change in a threshold voltage distribution of the memory cell by first writing in a first writing scheme in the memory system;

FIG. 10 is a diagram illustrating a change in a threshold voltage distribution of the memory cell by second writing in the first writing scheme in the memory system;

FIG. 11 is a diagram illustrating transition of a state of the memory cell by a 1-step write operation;

FIG. 12 is a diagram illustrating transition of a state of the memory cell by 2-step write operation executed in the memory system;

FIG. 13 is a diagram illustrating a change in a threshold voltage distribution of the memory cell in a second writing scheme in the memory system;

FIG. 14 is a diagram illustrating a change in a threshold voltage distribution of the memory cell in a third writing scheme in the memory system;

FIG. 15 is a diagram illustrating an example of a writing order of a 2-step write operation executed according to a first comparative example;

FIG. 16 is a diagram illustrating an example of a writing order of a 2-step write operation executed according to a second comparative example;

FIG. 17 is a diagram illustrating an example of a writing order of a 2-step write operation executed according to a third comparative example;

FIG. 18 is a diagram illustrating an example of writing order of a 1-step write operation and a 2-step write operation executed according to a fourth comparative example;

FIG. 19 is a diagram illustrating a first example of a writing order of a 2-step write operation executed according to the embodiment;

FIG. 20 is a diagram illustrating a second example of the writing order of the 2-step write operation;

FIG. 21 is a diagram illustrating a third example of the writing order of the 2-step write operation;

FIG. 22 is a diagram illustrating three types of 2-step writing schemes;

FIG. 23 is a diagram illustrating three types of writing patterns;

FIG. 24 is a diagram illustrating an example of a command sequence used in a data write process of the memory system;

FIG. 25 is a flowchart illustrating a procedure of a first data write process executed in the memory system; and

FIG. 26 is a flowchart illustrating a procedure of a second data write process executed in the memory system.

### DETAILED DESCRIPTION

Embodiments provide a memory system capable of reducing a size of data required to be stored in a program operation on a nonvolatile memory.

In general, according to an embodiment, a memory system includes a nonvolatile memory and a memory controller. The nonvolatile memory includes a first array of memory cells connected to a first group of word lines, a second array of memory cells connected to a second group of word lines, and a third array of memory cells connected to a boundary word line extending between the first group of word lines and the second group of word lines. The memory controller is configured to perform a two-step program operation of a first type to write multi-bit data with respect to each memory cell in the first and second arrays. The two-step program operations of the first type includes a first program operation to set a threshold voltage of the memory cell to be in one of a first plurality of threshold voltage ranges with overlaps thereamong, and then a second program operation to set the threshold voltage to be in one of a second plurality of threshold voltage ranges without overlap thereamong. The memory controller is configured to perform a two-step program operation of a second type to write multi-bit data with respect to each memory cell in the third array. The two-step program operations of the second type includes a third program operation to set the threshold voltage to be in one of a third plurality of threshold voltage ranges corresponding to partial, but not entire, bits of the multi-bit data, and then a fourth program operation to set the threshold voltage to be in one of a fourth plurality of threshold voltage ranges corresponding to the entire bits of the multi-bit data.

Hereinafter, embodiments will be described with reference to the drawings.

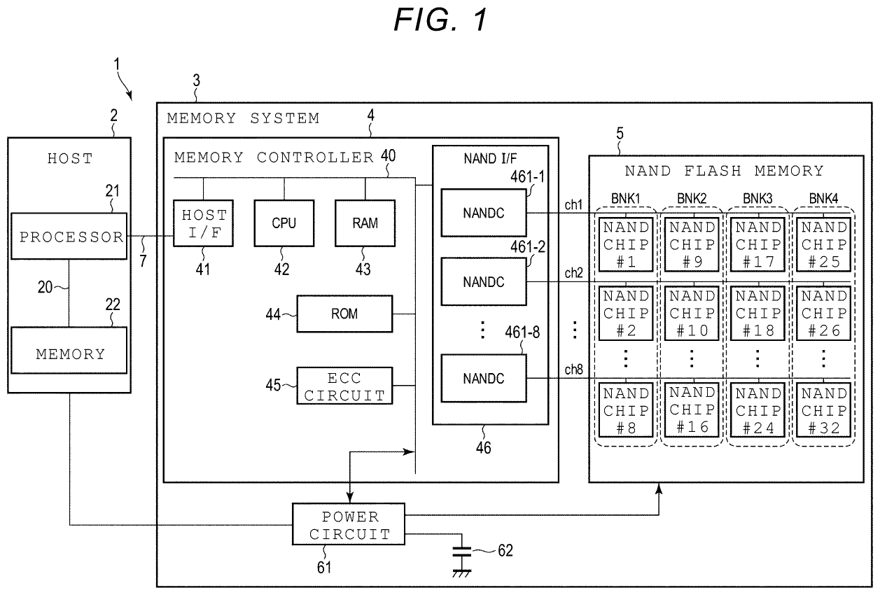

FIG. 1 is a block diagram illustrating a configuration example of an information processing system 1 including a memory system 3 according to an embodiment. The memory system 3 according to the embodiment is a storage device that includes a nonvolatile memory.

The information processing system 1 includes a host device (host) 2 and the memory system 3. The host 2 and the memory system 3 are connected to each other via a bus 7.

The host 2 is an information processing device. The host 2 is, for example, a personal computer, a server computer, or a portable terminal. The host 2 accesses the memory system 3. Specifically, the host 2 transmits, to the memory system 3, a write command that is a command for requesting to write data into the nonvolatile memory. The host 2 transmits, to the memory system 3, a read command that is a command for requesting to read data from the nonvolatile memory.

The memory system 3 is a semiconductor storage device in which data is written on a nonvolatile memory and data is read from the nonvolatile memory. The memory system 3 is connected to the host 2 to be able to communicate with the host 2. The memory system 3 is implemented with, for example, a solid state device (SSD) or an SD™ card. The nonvolatile memory is, for example, a NAND flash memory 5.

The memory system 3 may be used as a storage of the host 2. The memory system 3 may be embedded in the host 2 or may be connected to the host 2 via a cable or a network.

Communication between the memory system 3 and the host 2 is executed via the bus 7. The bus 7 is used to transmit data and an input/output command (I/O command) from the host 2 to the memory system 3 and transmit data and a response from the memory system 3 to the host 2. The I/O command is a command for writing or reading data on or from the NAND flash memory 5. Examples of the I/O command include a write command for requesting to write data on the NAND flash memory 5 and a read command for requesting to read data from the NAND flash memory 5.

An interface for connecting the memory system 3 and the host 2 conforms to a standard such as an SCSI, a serial attached SCSI (SAS), an AT attachment (ATA), a serial ATA (SATA), a PCI Express™ (PCIe™), Ethernet™, a Fibre channel, and an NVM Express™ (NVMe™).

Next, an internal configuration of the memory system 3 will be described. The memory system 3 includes a memory controller 4, the NAND flash memory 5, and a power circuit 61. The memory system 3 may further include a dynamic random access memory (DRAM) (not illustrated). The DRAM is a volatile memory. A storage region of the DRAM may be used, for example, to temporarily store data for managing the memory system 3, data read from the NAND flash memory 5, and data to be written into the NAND flash memory 5.

The memory controller 4 is a memory controller that controls the NAND flash memory 5. The memory controller 4 is, for example, a control circuit such as a system-on-a-chip (SoC). The memory controller 4 is electrically connected to the NAND flash memory 5. The memory controller 4 processes various commands received from the host 2. The memory controller 4 executes writing of data on the NAND flash memory 5 by processing a write command. The memory controller 4 executes reading of data from the NAND flash memory 5 by processing a read command.

The memory controller 4 functions as, for example, a flash translation layer (FTL) configured to execute data management and block management of the NAND flash memory 5. The data management executed by the FTL includes management of mapping information indicating a correspondence relation between each logical address and each physical address of the NAND flash memory 5. The block management includes management of defective blocks, wear leveling, and garbage collection (compaction).

A logical address is used by the host 2 to designate an address of a storage region of the memory system 3. The logical address is, for example, a logical block address (LBA).

A physical address is an address for designating a storage position in the NAND flash memory 5. The physical address is, for example, a physical block address (PBA).

Management of mapping between each logical address and each physical address is executed, for example, using a logical-physical address conversion table. The memory controller 4 manages mapping between each logical address and each physical address in units of a specific management size using the logical-physical address conversion table. A physical address corresponding to a certain logical address indicates a physical storage position in the NAND flash memory 5 in which user data of the logical address is written. The logical-physical address conversion table may be loaded from the NAND flash memory 5 into the DRAM when the memory system 3 starts up.

Writing data of one page can be executed only once per one P/E cycle. Therefore, the memory controller 4 writes update user data corresponding to a certain logical address not into a physical storage position at which previous user data corresponding to the logical address is stored but into another physical storage position. The memory controller 4 invalidates the previous user data by updating the logical-physical address conversion table such that the logical address is associated with the other physical storage position.

The NAND flash memory 5 is a nonvolatile memory. The NAND flash memory 5 is, for example, a flash memory having a three-dimensional structure. The NAND flash memory 5 includes a plurality of memory cells arranged in a matrix configuration. Each of the plurality of memory cells can store, for example, 4-bit data. The data stored in each of the plurality of memory cells may be data of 4-bit or less. An operation of writing 4-bit data per memory cell is referred to as a QLC program operation, an operation of writing 3-bit data per memory cell is referred to as a TLC program operation, an operation of writing 2-bit data per memory cell is referred to as an MLC program operation, and an operation of writing 1-bit data per memory cell is referred to as an SLC program operation.

Next, an example of an internal configuration of the memory controller 4 will be described. The memory controller 4 includes a host interface (host I/F) 41, a CPU 42, a random access memory (RAM) 43, a read only memory (ROM) 44, an ECC circuit 45, and a NAND interface (NAND I/F) 46. These components of the memory controller 4 are connected to each other via an internal bus 40. A function of each component of the memory controller 4 may be implemented by dedicated hardware, may be implemented by a processor executing a program, or may be implemented by a combination of dedicated hardware and a processor. The memory controller 4 executes communication with the host 2.

The host interface 41 is an interface circuit that executes communication with the host 2. The host interface 41 receives, for example, an I/O command and data from the host 2. The host interface 41 transmits data and a response to the host 2.

The CPU 42 is a processor. The CPU 42 controls the host interface 41, the ECC circuit 45, and the NAND interface 46. The CPU 42 loads a control program (e.g., firmware) stored in the NAND flash memory 5 or the ROM 44 into the RAM 43. The CPU 42 performs various processes by executing the control program (e.g., firmware) loaded into the RAM 43.

The RAM 43 is a volatile memory. A part of a storage region of the RAM 43 is used to, for example, temporarily store information used to manage the memory system 3. Another part of the storage region of the RAM 43 may be used to temporarily store write data received from the host 2 or read data read from the NAND flash memory 5.

The ROM 44 is a nonvolatile memory. For example, the ROM 44 stores firmware for controlling an operation of the entire memory controller 4.

The ECC circuit 45 is a circuit that executes an encoding process and a decoding process. The ECC circuit 45 executes the encoding process on data to be written into the NAND flash memory 5. The ECC circuit 45 executes the decoding process on data to be read from the NAND flash memory 5. In the encoding process, the ECC circuit 45 generates an error correction code and assigns the generated error correction code to data to be written. In the decoding process, the ECC circuit 45 decodes the error correction code assigned to data read from the NAND flash memory 5 and detects an error bit. When an error bit is detected, the ECC circuit 45 specifies an error position and executes error correction.

The NAND interface 46 is a circuit that controls the NAND flash memory 5 under control of the CPU 42. The NAND interface 46 is electrically connected to a plurality of NAND chips in the NAND flash memory 5.

The plurality of NAND chips can independently operate. Therefore, the NAND chips can function as units that can be operated in parallel. The NAND interface 46 includes, for example, a plurality of NAND controllers (NANDC) 461-1, 462-2, . . . , and 461-8. The NANDC 461-1, 461-2, . . . , and 461-8 are connected to channels ch1, ch2, . . . , and ch8, respectively. Each of the NANDC 461-1, 461-2, . . . , and 461-8 are connected to one NAND chip or a plurality of NAND chips via a corresponding channel. In FIG. 1, as an example, four NAND chips are connected to each of the channels ch1, ch2, . . . , and ch8. Here, the NANDC 461-1 is connected to a NAND chip #1, a NAND chip #9, a NAND chip #17, and a NAND chip #25 via the channel ch1. The NANDC 461-2 is connected to a NAND chip #2, a NAND chip #10, a NAND chip #18, and a NAND chip #26. The NANDC 461-8 is connected to a NAND chip #8, a NAND chip #16, a NAND chip #24, and a NAND chip #32. The NAND chips #1, #2, . . . , and #8 are treated as a bank BNK1. The NAND chips #9, #10, . . . , and #16 are treated as a bank BNK2. The NAND chips #17, #18, . . . , and #24 are treated as a bank BNK3. The NAND chips #25, #26, . . . , and #32 are treated as a bank BNK4. A bank is a unit in which the plurality of NAND chips are operated in parallel by an interleaving operation.

The power circuit 61 is a circuit that distributes a power voltage received from the host 2 to each element of the memory system 3. The power circuit 61 supplies the power voltage to, for example, the memory controller 4 and the NAND flash memory 5. The power circuit 61 includes a capacitor 62.

The capacitor 62 is an element capable of storing power. When a value of the power voltage supplied from the host 2 is lowered without notification from the host 2, the power circuit 61 can temporarily supply power to the memory controller 4 and the NAND flash memory 5 using the power stored in the capacitor 62. For example, the memory controller 4 writes, into the NAND flash memory 5, data of which writing into the NAND flash memory 5 is not completed using the supplied power.

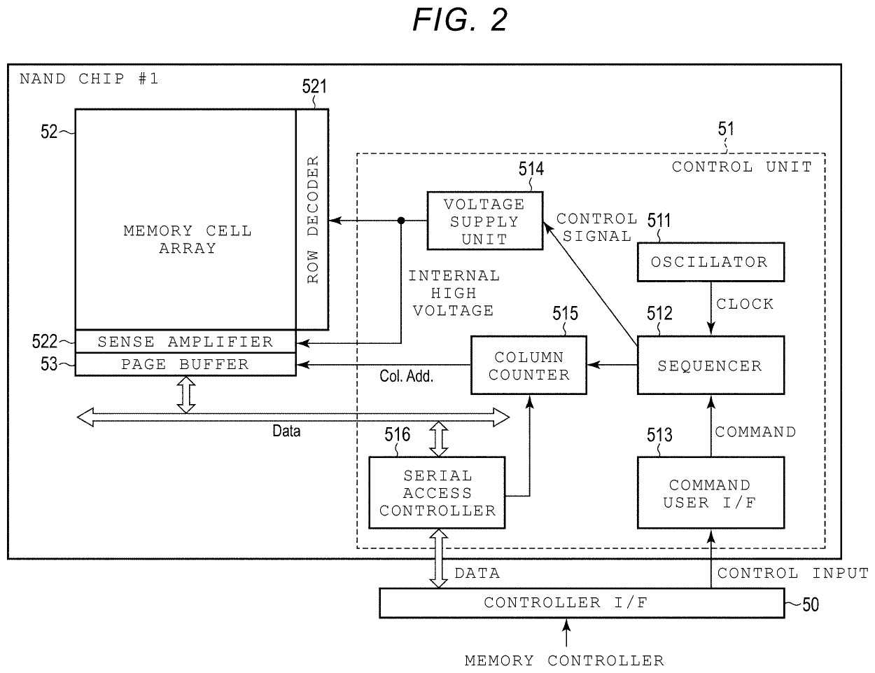

Next, a configuration example of the NAND chip of the NAND flash memory 5 will be described. FIG. 2 is a block diagram illustrating a configuration example of the NAND chip according to the embodiment. In FIG. 2, the NAND chip #1 is illustrated, and the other NAND chips have similar configurations to the NAND chip #1.

The NAND chip #1 is connected to the NANDC 461 of the memory controller 4 via a controller interface 50 of the NAND flash memory 5. The NAND chip #1 receives data to be written and a command from the NANDC 461. The NAND chip #1 transmits read data to the NANDC 461.

The NAND chip #1 includes a control unit 51, a memory cell array 52, and a page buffer 53.

The control unit 51 controls an operation of the NAND chip #1 based on a request received from the memory controller 4. Specifically, when a write request is received, the control unit 51 performs control such that data requested to be written is written into a designated address in the memory cell array 52. When a read request is received, the control unit 51 performs control such that data requested to be read is read from the memory cell array 52 and the data is transmitted to the memory controller 4 via the controller interface 50.

The page buffer 53 temporarily stores data input from the memory controller 4 when writing data on the memory cell array 52. The page buffer 53 temporarily stores data read from the memory cell array 52 when reading data from the memory cell array 52. During a program operation, the page buffer 53 sequentially stores data received from a serial access controller 516 in a column address region designated by a column counter 515. During a read operation, the page buffer 53 sequentially transmits data of a column address region designated by a column address among stored data to the serial access controller 516.

The control unit 51 includes an oscillator 511, a sequencer 512, a command user interface 513, a voltage supply unit 514, the column counter 515, and the serial access controller 516.

The oscillator 511 is a circuit that generates a clock signal. The clock signal generated by the oscillator 511 is supplied to each element including the sequencer 512.

The sequencer 512 is a state machine driven by the clock signal supplied from the oscillator 511. The sequencer 512 executes control of access to the memory cell array 52 or the like. For example, the sequencer 512 gives a command to control various internal voltages, operation timings, and the like in response to a command received from the command user interface 513. The sequencer 512 supplies a row decoder 521 with a block address and a page address included in an address received from the command user interface 513. The sequencer 512 supplies the column counter 515 with a column address included in an address received from the command user interface 513.

The command user interface 513 acquires a command and an address among commands, addresses, and data received via an I/O signal line from the memory controller 4 based on a control signal. The command user interface 513 delivers the acquired command address to the sequencer 512.

The voltage supply unit 514 generates various internal voltages to be supplied to word lines or various internal voltages to be supplied to bit lines, and supplies the generated internal voltages to the row decoder 521 or a sense amplifier 522.

During a program operation or a read operation, the column counter 515 sets a column address supplied from the sequencer 512 as a header and sequentially advances column addresses according to a control signal supplied from the serial access controller 516.

During the program operation, the serial access controller 516 stores, in the page buffer 53, data received in series for each bit width of the I/O signal line from the controller interface 50. During the read operation, the serial access controller 516 transmits, to the controller interface 50, data received in series for each bit width of the I/O signal line from the page buffer 53.

The memory cell array 52 includes the row decoder 521 and the sense amplifier 522.

During the program operation and the read operation, the row decoder 521 decodes a block address and a page address and selects a word line corresponding to an access target page included in a block BLK as an access destination. Then, the row decoder 521 applies voltages appropriate for a selected word line and a non-selected word line.

During the program operation, the sense amplifier 522 transmits the corresponding data stored in the page buffer 53 to the memory cell. During the read operation, the sense amplifier 522 senses data read from the selected word line to the bit line and stores the sensed data in the page buffer 53. The data stored in the page buffer 53 is transmitted to the memory controller 4 via the serial access controller 516 and the controller interface 50.

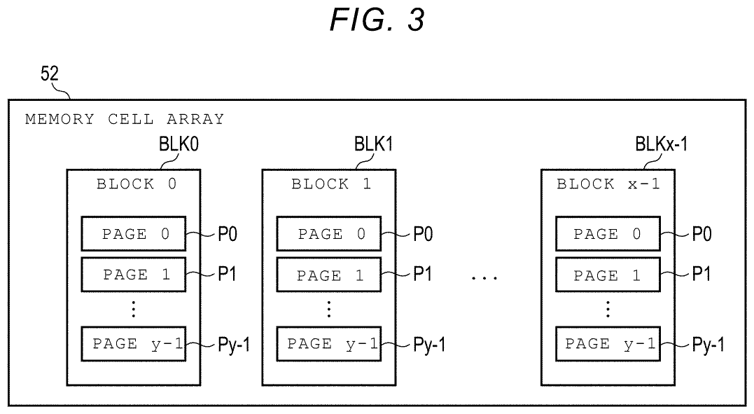

Next, an example of an internal configuration of the memory cell array 52 will be described. FIG. 3 is a block diagram illustrating an example of an internal configuration of the memory cell array 52 according to the embodiment.

The memory cell array 52 includes a plurality of blocks BLK0 to BLKx−1. Each of the blocks BLK0 to BLKx−1 functions as a unit of a data erase operation. The data erase operation is also referred to as an erase operation. Each of the blocks BLK0 to BLKx−1 is referred to as a physical block, a flash block, or a memory block.

Each of the blocks BLK0 to BLKx−1 includes a plurality of pages P0 to Py−1. Each of the pages P0 to Py−1 is a unit of a data write operation and a data read operation. Each of the pages P0 to Py−1 includes, for example, a plurality of memory cells connected to the same word line.

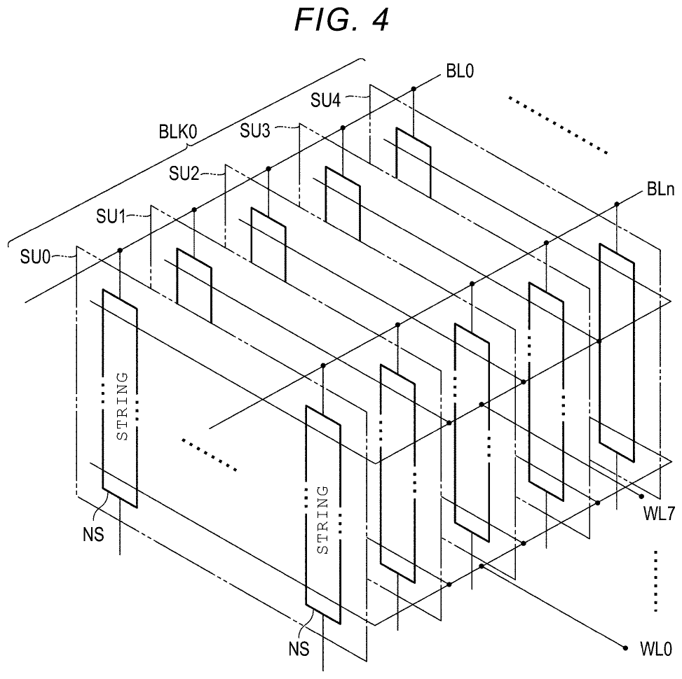

Next, a configuration example of the block will be described. FIG. 4 is a diagram illustrating a configuration example of each of a plurality of blocks in the memory cell array 52 of the NAND flash memory 5 of the memory system 3 according to the embodiment.

In FIG. 4, a configuration of the block will be described focusing on the block BLK0. For example, the other blocks have similar configurations to the block BLK0. The block BLK0 includes five string units (SU0, SU1, SU2, SU3, and SU4). Any suitable numbers of string units SU in each block BLK may be used. The five string units (SU0, SU1, SU2, SU3, and SU4) are disposed in a direction (horizontal direction) orthogonal to a direction (vertical direction) in which a plurality of word lines WL0 to WL7 are stacked. Each string unit SU includes a plurality of strings NS. One end of each string NS is connected to a corresponding bit line among a plurality of bit lines (BL0 to BLn). Each string NS extends in the vertical direction. Control gates of a plurality of memory cells in each string NS are connected to the plurality of word lines (WL0, WL1, . . . , and WL7), respectively. The number of word lines may be nine or more.

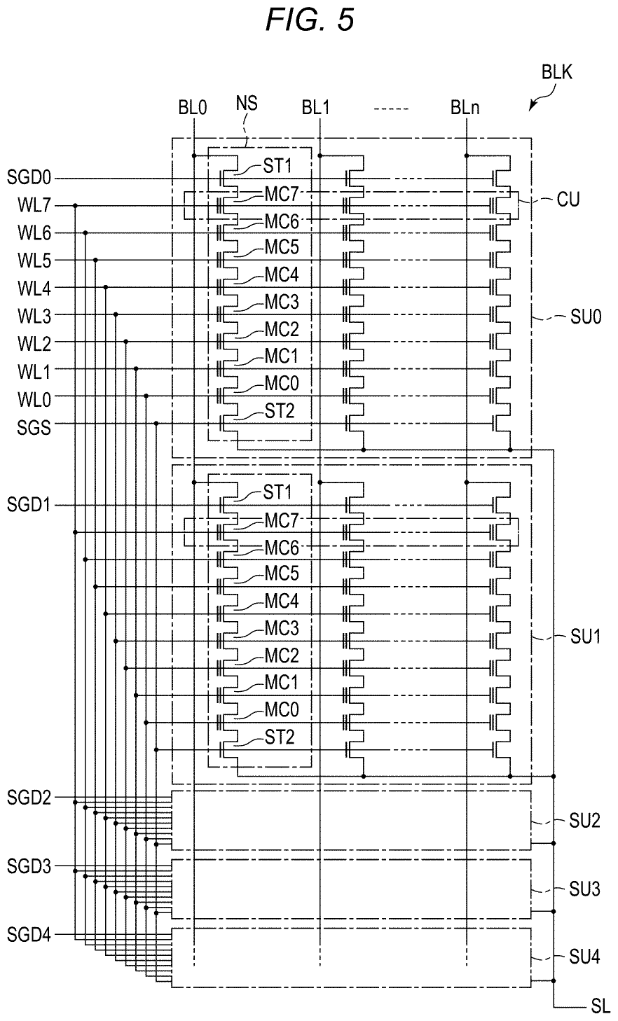

Next, a circuit configuration of the block in the memory cell array 52 will be described. FIG. 5 is a diagram illustrating a configuration example of a circuit of the block of the NAND flash memory 5 according to the embodiment.

In FIG. 5, the string units SU0 to SU4 in a certain block BLK are illustrated.

The string unit SU is a set of a plurality of strings NS selected collectively in a program operation or a read operation, for example. Each string unit SU includes a plurality of strings NS.

Each string NS is a set of a plurality of memory cells MC connected in series. The plurality of strings NS in the string unit SU are connected to any of bit lines BL0 to BLn (where n is an integer of 1 or more). The string NS includes a plurality of memory cells MC and select transistors ST1 and ST2. In the example of FIG. 5, the string NS includes eight memory cells MC0 to MC7 and two select transistors ST1 and ST2. The number of the memory cells MC in the string NS is not limited to eight.

The memory cell MC is a memory element that stores data in a nonvolatile manner. The memory cell MC includes a control gate and a charge storage layer. The memory cell MC may be a metal-oxide-nitride-oxide-silicon (MONOS) type memory cell or a floating gate (FG) type memory cell. In the MONOS type memory cell, an insulating layer is used as the charge storage layer. In the FG type memory cell, a conductive layer is used as the charge storage layer.

The select transistors ST1 and ST2 are switching elements. The select transistors ST1 and ST2 are each used to select the string unit SU in various operations.

A gate of each select transistor ST1 of the string unit SU0 is connected to a select gate line SGD0 corresponding to the string unit SU0. A gate of each select transistor ST1 of the string unit SU1 is connected to a select gate line SGD1 corresponding to the string unit SU1. A gate of each select transistor ST1 of the string unit SU2 is connected to a select gate line SGD2 corresponding to the string unit SU2. A gate of each select transistor ST1 of the string unit SU3 is connected to a select gate line SGD3 corresponding to the string unit SU3. A gate of each select transistor ST1 of the string unit SU4 is connected to a select gate line SGD4 corresponding to the string unit SU4. Meanwhile, gates of the select transistors ST2 of the string units SU0 to SU4 are commonly connected to a select gate line SGS. The gates of the select transistors ST2 of the string units SU0 to SU4 may be connected to different select gate lines for each string unit. Each of control gates of the memory cells MC0 to MC7 in the same block BLK are commonly connected to the word lines WL0 to WL7.

A program operation and a read operation in the NAND flash memory 5 can be collectively executed on a plurality of memory cells MC connected to one word line in one string unit SU. During the program operation and the read operation, a set of the collectively selected memory cells MC is referred to as a memory cell group MG. The memory cell group MG is a unit of the program operation and the read operation and may be treated as a storage position. When each memory cell MC is configured to store 1-bit data, the size of data stored per memory cell group MG is referred to as a page. When each memory cell MC is configured to store 4-bit data, the size of data stored per memory cell group MG is four pages. Hereinafter, the memory cell group MG is simply referred to as a memory cell.

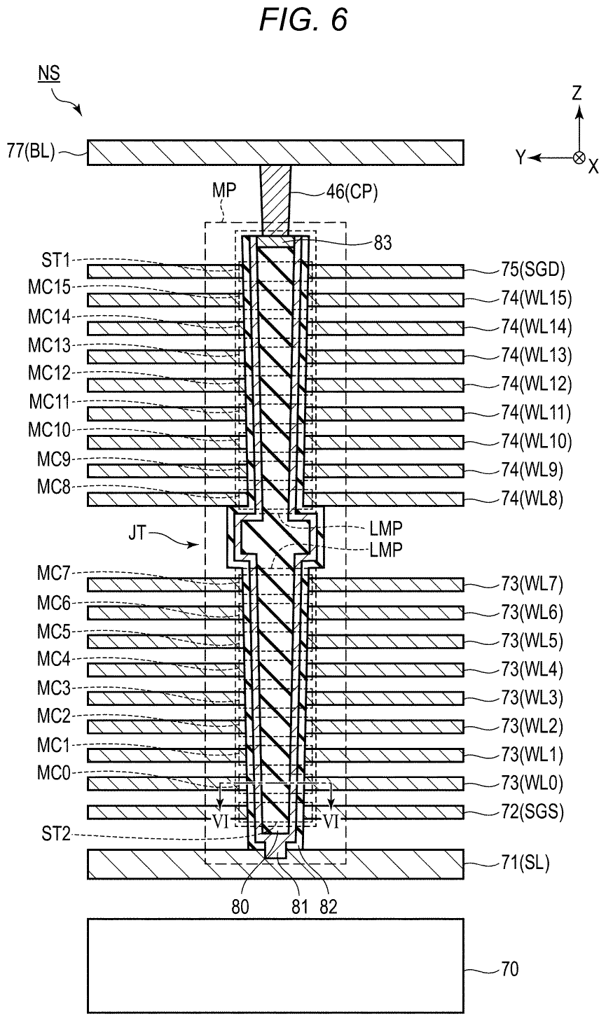

Next, a cross-sectional structure of the string NS will be described. FIG. 6 is a cross-sectional diagram illustrating the string NS that is a partial region of the block BLK. As illustrated in FIG. 6, a memory pillar MP formed above a semiconductor substrate 70 is used as the string NS.

In cross-sectional views referred to below, an X axis corresponds to an extension direction of the word line WL, a Y axis corresponding to an extension direction of the bit line BL, and a Z axis corresponds to an extension direction of the string NS in the semiconductor substrate 70. To facilitate understanding of the drawings, elements such as insulating layers (interlayer insulating films) are appropriately omitted.

The memory pillar MP formed above the semiconductor substrate 70 (in an arrow direction of the Z axis) is used as the string NS.

A conductive layer 71 is provided above the semiconductor substrate 70 with an insulating layer (not illustrated) interposed therebetween. In the insulating layer, for example, a peripheral circuit such as the sense amplifier 522 may be provided. The conductive layer 71 is formed in a plate shape spreading in, for example, an XY plane and is used as a source line SL.

A conductive layer 72 is provided above the conductive layer 71 with an insulating layer (not illustrated) interposed therebetween. The conductive layer 72 is used as the select gate line SGS.

Insulating layers (not illustrated) and conductive layers 73 are alternately stacked a plurality of times (eight times in FIG. 6) above the conductive layer 72. The plurality of conductive layers 73 are respectively used as the word lines WL0 to WL7 in order from the semiconductor substrate 70 side.

Insulating layers (not illustrated) and conductive layers 74 are alternately stacked a plurality of times (eight in FIG. 6) above the uppermost conductive layer 73. The plurality of conductive layers 74 are respectively used as word lines WL8 to WL15 in order from the semiconductor substrate 70 side. An interval between the uppermost conductive layer 73 and the lowermost conductive layer 74 is greater than an interval between the adjacent conductive layers 73 or an interval between the adjacent conductive layers 74.

A conductive layer 75 is provided above the uppermost conductive layer 74 with an insulating layer (not illustrated) interposed between. The conductive layer 75 is used as a select gate line SGD. The conductive layers 72 to 75 are formed in a plate shape spreading in, for example, the XY plane.

Conductive layers 77 are provided above the conductive layer 75 with an insulating layer (not illustrated) interposed therebetween. The conductive layers 77 extend in the Y axis, are arranged in a line shape along the X axis, and are used as the bit line BL, respectively.

The memory pillar MP is provided to extend in the Z axis, penetrates through the conductive layers 72 to 75, and is in contact with the conductive layer 71 by a lower portion of the memory pillar MP. The memory pillar MP includes a lower pillar LMP, an upper pillar UMP formed above the lower pillar LMP, and a joint portion JT electrically connecting the lower pillar LMP to the upper pillar UMP. The lower pillar LMP and the upper pillar UMP have, for example, a taper shape of which diameter increases from the semiconductor substrate 70 to the bit line BL (along the Z axis). For example, the diameter of the joint portion JT in the XY plane is larger than the diameter of the lower pillar LMP and smaller than the diameter of the upper pillar UMP.

The memory pillar MP includes, for example, a core film 80, a semiconductor film 81, a stacked film 82, and a semiconductor portion 83. For example, the core film 80, the semiconductor film 81, and the stacked film 82 are formed as continuous films in the lower pillar LMP, the joint portion JT, and the upper pillar UMP.

Specifically, the core film 80 is provided substantially at the center of the memory pillar MP and extends in the Z axis. The core film 80 has, for example, an upper end located above the conductive layer 75 and a lower end located below the conductive layer 72. The core film 80 includes, for example, an insulator such as silicon oxide (SiO2).

The semiconductor film 81 covers a bottom surface and a side surface of the core film 80 and includes a cylindrical portion formed along the Z axis. The semiconductor film 81 has an upper end located above the conductive layer 75 and a lower end in contact with the conductive layer 71. The semiconductor film 81 includes, for example, polysilicon.

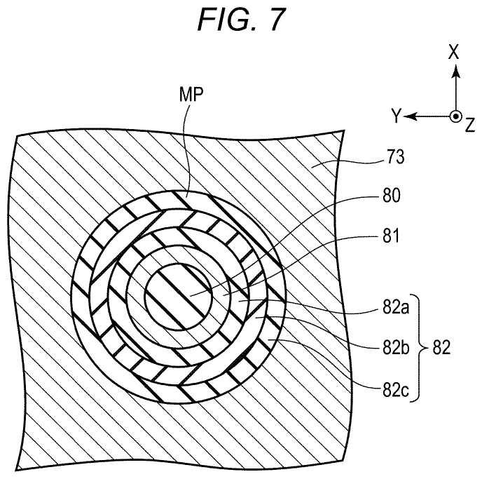

The stacked film 82 covers a side surface of the semiconductor film 81 and includes a cylindrical portion formed along the Z axis. Details of the structure of the stacked film 82 will be described with reference to FIG. 7 that shows a cross-sectional view taken along the line VI-VI of FIG. 6.

As illustrated in FIG. 7, the stacked film 82 includes a tunnel insulating film 82a, a charge storage film 82b, and a block insulating film 82c. The tunnel insulating film 82a covers the side surface of the semiconductor film 81 and the charge storage film 82b covers a side surface of the tunnel insulating film 82a. The block insulating film 82c covers a side surface of the charge storage film 82b and is covered by the conductive layer 73.

Referring back to FIG. 6, a configuration of the memory pillar MP will be described. The semiconductor portion 83 covers an upper surface of the core film 80 and is in contact with a portion of the semiconductor film 81 above the core film 80. The semiconductor portion 83 has, for example, a cylindrical shape and is located at the upper end of the upper pillar UMP.

A conductive layer 76 is provided between an upper surface of the semiconductor portion 83 and a lower surface of the conductive layer 77. The conductive layer 76 is used as a contact CP that electrically connects the memory pillar MP to the bit line BL.

In the above-described structure of the memory pillar MP, a portion in which the lower pillar LMP intersects the conductive layer 72 functions as the select transistor ST2. Portions in which the lower pillar LMP intersects the plurality of conductive layers 73 function as the memory cells MC0 to MC7, respectively. Portions in which the upper pillar UMP intersects the plurality of conductive layers 74 function as memory cells MC8 to MC15, respectively. A portion in which the upper pillar UMP intersects the conductive layer 75 functions as the select transistor ST1. The semiconductor film 81 functions as a channel of each of the memory cells MC and the select transistors ST1 and ST2.

The above-described structure enables the memory pillar MP to function as the string NS. A plurality of memory pillars MP are disposed above the semiconductor substrate 70, and thus the memory cell array 52 is formed. FIG. 6 illustrates a 2-tier structure in which two memory pillars MP are disposed, but a 3-tier structure in which three or more memory pillars are disposed above the semiconductor substrate 70 may be used.

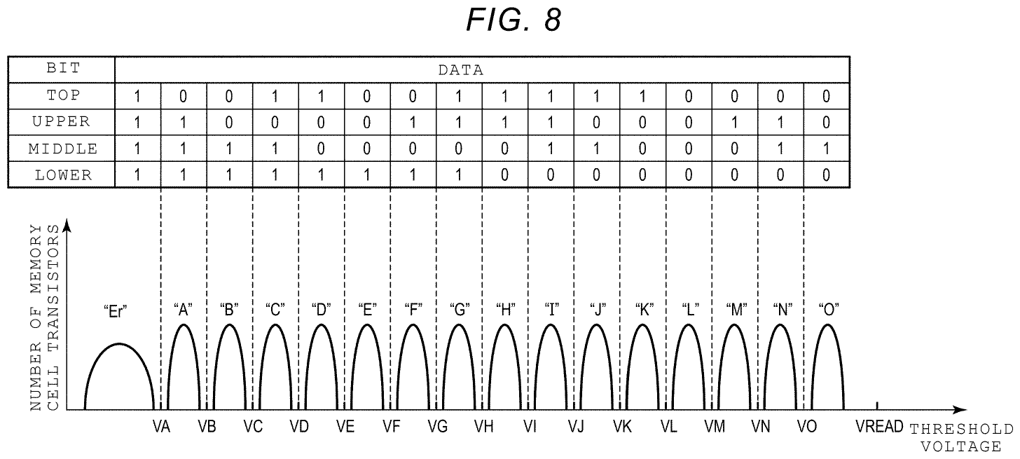

Next, a threshold voltage distribution in the memory cell MC will be described. FIG. 8 is a diagram schematically illustrating a threshold voltage distribution of the memory cell MC according to the embodiment.

The NAND flash memory 5 can store data of 4-bit or less per memory cell MC. FIG. 8 illustrates a threshold voltage distribution when 4-bit data is stored per memory cell MC by a data write process in the memory system 3 according to the embodiment. A threshold voltage of each memory cell MC has a value corresponding to the stored data. When 4-bit data is stored per memory cell MC, each memory cell MC can have any of 16 (=2⁴) threshold voltages. The 16 threshold voltages are states each storing “1111” data, “0111” data, “0011” data, “1011” data, “1001” data, “0001” data, “0101” data, “1101” data, “1100” data, “1110” data, “1010” data, “1000” data, “0000” data, “0100” data, “0110” data, and “0010” data. The memory cells MC that store “1111” data, “0111” data, “0011” data, “1011” data, “1001” data, “0001” data, “0101” data, “1101” data, “1100” data, “1110” data, “1010” data, “1000” data, “0000” data, “0100” data, “0110” data, and “0010” data are referred to as being in Er, A, B, C, D, E, F, G, H, I, J, K, L, M, N, and O states, respectively. The memory cells MC in the Er state, the A state, the B state, the C state, the D state, the E state, the F state, the G state, the H state, the I state, the J state, the K state, the L state, the M state, the N state, and the O state have higher threshold voltages in this order.

Even when a plurality of memory cells MC store the same 4-bit data, the plurality of memory cells MC can have different threshold voltages due to a variation in characteristics of the memory cells MC. Nevertheless, the threshold voltages of the plurality of memory cells MC storing the same 4-bit data are included in the same state. In FIG. 8 and the subsequent drawings, threshold voltage distributions are illustrated as continuous curves. However, in practice, the number of memory cells MC are discrete.

To distinguish data stored by a read target memory cell MC, a state of the memory cell MC is determined. To determine the state, read voltages VA, VB, VC, VD, VE, VF, VG, VH, VI, VJ, VK, VL, VM, VN, and VO are used. Hereinafter, a voltage of a certain magnitude applied to the read target memory cell MC to determine a state of the memory cell MC, including the read voltages VA, VB, VC, VD, VE, VF, VG, VH, VI, VJ, VK, VL, VM, VN, and VO, may be referred to as a read voltage VCGR.

The read voltage VA is higher than a highest threshold voltage of the memory cell MC in the Er state and is lower than a lowest threshold voltage of the memory cell MC in the A state directly after writing.

The read voltage VB is higher than a highest threshold voltage of the memory cell MC in the A state directly after writing and is lower than a lowest threshold voltage of the memory cell MC in the B state directly after writing.

The read voltage VC is higher than a highest threshold voltage of the memory cell MC in the B state directly after writing and is lower than a lowest threshold voltage of the memory cell MC in the C state directly after writing.

The read voltage VD is higher than a highest threshold voltage of the memory cell MC in the C state directly after writing and is lower than a lowest threshold voltage of the memory cell MC in the D state directly after writing.

The read voltage VE is higher than a highest threshold voltage of the memory cell MC in the D state directly after writing and is lower than a lowest threshold voltage of the memory cell MC in the E state directly after writing.

The read voltage VF is higher than a highest threshold voltage of the memory cell MC in the E state directly after writing and is lower than a lowest threshold voltage of the memory cell MC in the F state directly after writing.

The read voltage VG is higher than a highest threshold voltage of the memory cell MC in the F state directly after writing and is lower than a lowest threshold voltage of the memory cell MC in the G state directly after writing.

The read voltage VH is higher than a highest threshold voltage of the memory cell MC in the G state directly after writing and is lower than a lowest threshold voltage of the memory cell MC in the H state directly after writing.

The read voltage VI is higher than a highest threshold voltage of the memory cell MC in the H state directly after writing and is lower than a lowest threshold voltage of the memory cell MC in the I state directly after writing.

The read voltage VJ is higher than a highest threshold voltage of the memory cell MC in the I state directly after writing and is lower than a lowest threshold voltage of the memory cell MC in the J state directly after writing.

The read voltage VK is higher than a highest threshold voltage of the memory cell MC in the J state directly after writing and is lower than a lowest threshold voltage of the memory cell MC in the K state directly after writing.

The read voltage VL is higher than a highest threshold voltage of the memory cell MC in the K state directly after writing and is lower than a lowest threshold voltage of the memory cell MC in the L state directly after writing.

The read voltage VM is higher than a highest threshold voltage of the memory cell MC in the L state directly after writing and is lower than a lowest threshold voltage of the memory cell MC in the M state directly after writing.

The read voltage VN is higher than a highest threshold voltage of the memory cell MC in the M state directly after writing and is lower than a lowest threshold voltage of the memory cell MC in the N state directly after writing.

The read voltage VO is higher than a highest threshold voltage of the memory cell MC in the N state directly after writing and is lower than a lowest threshold voltage of the memory cell MC in the O state directly after writing.

The read voltages VA, VB, VC, VD, VE, VF, VG, VH, VI, VJ, VK, VL, VM, VN, and VO are, for example, default voltages. Reading in which a read voltage VX (where X is A, B, C, D, E, F, G, H, I, J, K, L, M, N, or O) is used is referred to as X reading (XR).

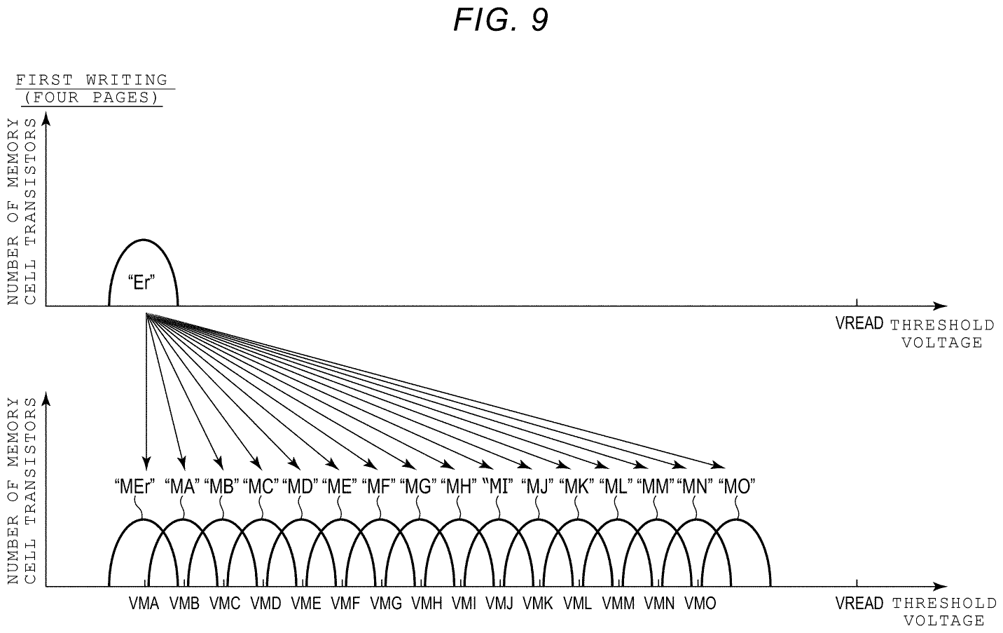

Next, a foggy-fine program operation that is a first writing scheme in a 2-step write operation will be described. In the foggy-fine program operation, a foggy program operation that is a first-step program operation will be described with reference to FIG. 9.

FIG. 9 is a diagram illustrating a change in a distribution of the threshold voltage of the memory cell MC by the first-step program operation executed by the memory system 3 according to the embodiment.

The NAND flash memory 5 executes the first-step program operation based on a command received from the memory controller 4 and data with a 4-page size. The data with the 4-page size is written into a top page, an upper page, a middle page, and a lower page of a writing destination memory cell. Each piece of data is referred to as, for example, top-page data, upper-page data, middle-page data, and lower-page data. The sequencer 512 executes the first-step program operation based on the top-page data, the upper-page data, the middle-page data, and the lower-page data. As the first-step program operation, the NAND flash memory 5 executes the foggy program operation that is coarse writing for increasing the threshold voltage of the memory cell MC in an incomplete manner based on data to be written.

The memory cell MC before execution of the foggy program operation is in the Er state. In the foggy program operation, for verification, the sequencer 512 uses verification voltages VMA, VMB, VMC, VMD, VME, VMF, VMG, VMH, VMI, VMJ, VMK, VML, VMM, VMN, and VMO. The verification voltages VMA, VMB, VMC, VMD, VME, VMF, VMG, VMH, VMI, VMJ, VMK, VML, VMM, VMN, and VMO are used to verify the memory cells MC to be written as the A, B, C, D, E, F, G, H, I, J, K, L, M, N, and O states, respectively. That is, for example, in verification in the foggy program operation of the memory cell MC to be written as the A state, the verification voltage VMA is used. The memory cell MC to be written as the A state passes the verification of the foggy program operation when the memory cell MC has a threshold voltage of the verification voltage VMA or more in the foggy program operation. The same applies to the other states. The verification voltages VMA, VMB, VMC, VMD, VME, VMF, VMG, VMH, VMI, VMJ, VMK, VML, VMM, VMN, and VMO have the following magnitude:
VMA<VA;
VMA<VMB<VB;
VMB<VMC<VC;
VMC<VMD<VD;
VMD<VME<VE;
VME<VMF<VF;
VMF<VMG<VG;
VMG<VMH<VH;
VMH<VMI<VI;
VMI<VMJ<VJ;
VMJ<VMK<VK;
VMK<VML<VL;
VML<VMM<VM;
VMM<VMN<VN; and
VMN<VMO<VO.

By the foggy program operation, the memory cell MC results in one of MEr, MA, MB, MC, MD, ME, MF, MG, MH, MI, MJ, MK, ML, MM, MN, and MO states, which have (partially) overlapped threshold voltage ranges with adjacent state(s). The memory cells MC to be written as the A, B, C, D, E, F, G, H, I, J, K, L, M, N, and O states, respectively, are in the MA, MB, MC, MD, ME, MF, MG, MH, MI, MJ, MK, ML, MM, MN, and MO states, respectively, directly after the foggy program operation is completed. The memory cell MC maintained in the Er state is maintained in the MEr state during the foggy program operation.

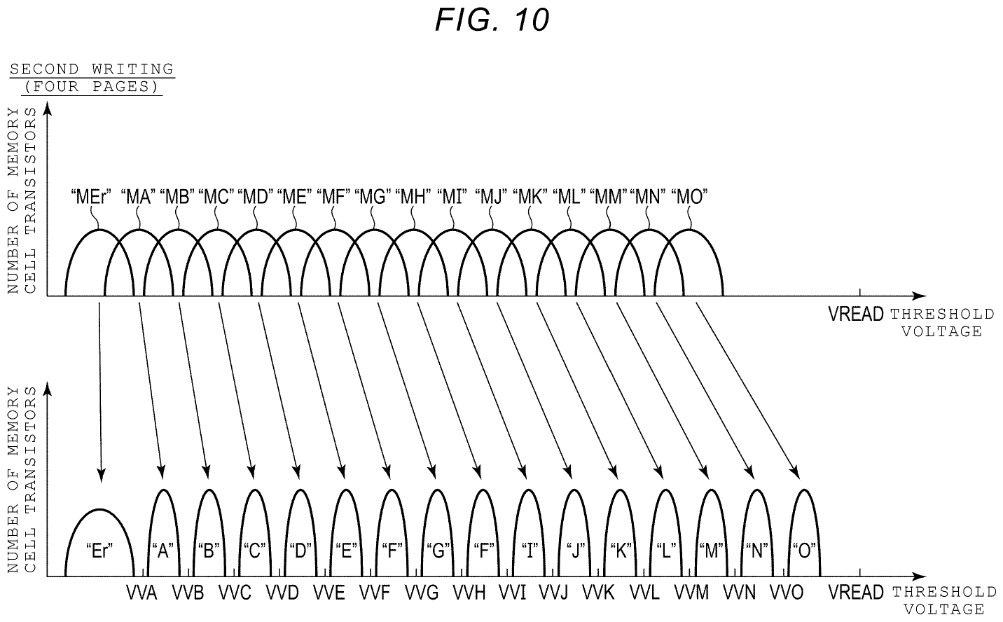

Subsequently, a fine program operation that is a second-step program operation in the foggy-fine program operation will be described with reference to FIG. 10. FIG. 10 is a diagram illustrating a change in a distribution of the threshold voltage of the memory cell MC by the second-step program operation in the first writing scheme in the memory system 3 according to the embodiment.

The NAND flash memory 5 receives data to be written into a writing destination memory cell MC from the memory controller 4. The data to be written is top-page data, upper-page data, middle-page data, and lower-page data similar to the data used in the foggy program operation. The NAND flash memory 5 executes the second-step program operation based on the received top-page data, upper-page data, middle-page data, and lower-page data. As the second-step program operation, the NAND flash memory 5 executes the fine program operation that is dense writing that completes an increase in the threshold voltage of the memory cell MC to complete writing.

In the fine program operation, the sequencer 512 uses verification voltages VVA, VVB, VVC, VVD, VVE, VVF, VVG, VVH, VVI, VVJ, VVK, VVL, VVM, VVN, and VVO. The verification voltages VVA, VVB, VVC, VVD, VVE, VVF, VVG, VVH, VVI, VVJ, VVK, VVL, VVM, VVN, and VVO are used to verify the memory cells MC to be written as the A, B, C, D, E, F, G, H, I, J, K, L, M, N, and O states, respectively, which have threshold voltage ranges with no overlap with adjacent state(s). That is, for example, the verification voltage VVA is used for verification in the fine program operation of the memory cell MC to be written as the A state. The memory cell MC to be written as the A state passes the verification of the fine program operation when the memory cell MC has a threshold voltage of the verification voltage VVA or more in the second-step program operation. The same applies to the other states. The verification voltages VVA, VVB, VVC, VVD, VVE, VVF, VVG, VVH, VVI, VVJ, VVK, VVL, VVM, VVN, and VVO have the following magnitude:
VA<VVA<VVB;
VB<VVB<VVC;
VC<VVC<VVD;
VD<VVD<VVE;
VE<VVE<VVF;
VF<VVF<VVG;
VG<VVG<VVH;
VH<VVH<VVI;
VI<VVI<VVJ;
VJ<VVJ<VVK;
VK<VVK<VVL;
VL<VVL<VVM;
VM<VVM<VVN;
VN<VVN<VVO; and
VO<VVO.

One purpose of the 2-step write operation is to prevent unintended transition of the threshold voltage of the memory cell MC of a cell unit CU in which writing is completed from a target state to a different state due to writing on adjacent cell unit CU.

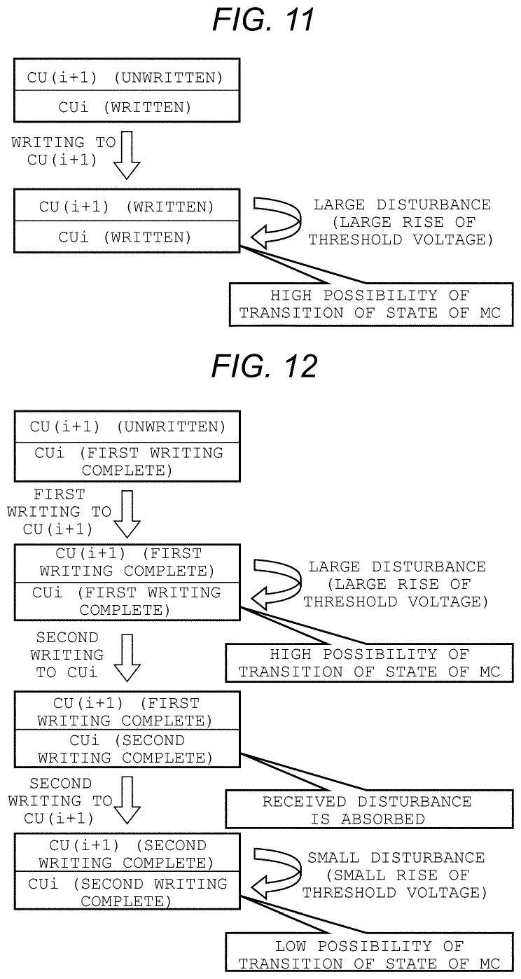

Therefore, an influence on close memory cells when a 1-step write operation is executed will be described. When the 1-step write operation is executed, the threshold voltage of the memory cell MC transitions from an upper-side state of FIG. 9 to a lower-side state of FIG. 10 without going through an upper-side state of FIG. 10. FIG. 11 is a diagram illustrating transition of a state of the memory cell by the 1-step write operation. The memory cells are referred to as, for example, a cell unit CU including a plurality of memory cells.

In the 1-step write operation, the memory cell MC transitions to a target state through a one-time writing, and the largest transition is transition of the threshold voltage from the Er state to the O state. When the 1-step write operation is executed on the cell unit CU(i+1) after writing on the cell unit CUi (where i is 0 or a natural number) as in FIG. 11, the threshold voltage of the memory cell MC of the cell unit CUi may rise unintentionally due to a rise of the threshold voltage of the memory cell MC in the cell unit CU(i+1). Since the rise is large, the state of the cell unit CUi may be significantly influenced. That is, when the 1-step writing is executed, disturbance occurring in close memory cells is large. As a result, the memory cell MC of the cell unit CUi may move to a state different from an intended state.

Next, an influence on the adjacent memory cells in execution of the 2-step write operation will be described. FIG. 12 is a diagram illustrating transition of a state of the memory cell by the 2-step write operation executed in the memory system 3 according to the embodiment.

In the 2-step write operation, as illustrated in FIG. 12, the first-step program operation is executed on the cell unit CU(i+1) after the first-step program operation is executed on the cell unit CUi. Here, in the memory cell MC of the cell unit CUi, the threshold voltage may rise due to the first-step program operation on the cell unit CU(i+1). However, thereafter, the threshold voltage of the memory cell MC in the cell unit CUi is controlled to a target state by the second-step program operation on the cell unit CUi. Accordingly, disturbance received due to the first-step program operation on the cell unit CU(i+1) is absorbed by the fine program operation that is the second-step program operation executed thereafter.

In the second-step program operation on the cell unit CU(i+1), disturbance can be caused to the cell unit CUi on which the second-step program operation is completed. However, since the rise of the threshold voltage by the second-step program operation is less than the rise of the threshold voltage by the first-step program operation, influence on the cell unit CUi on which the writing is completed is not great. Accordingly, the memory cell MC of the cell unit CUi is prevented from transitioning unintentionally from the state after the writing is completed to a different state.

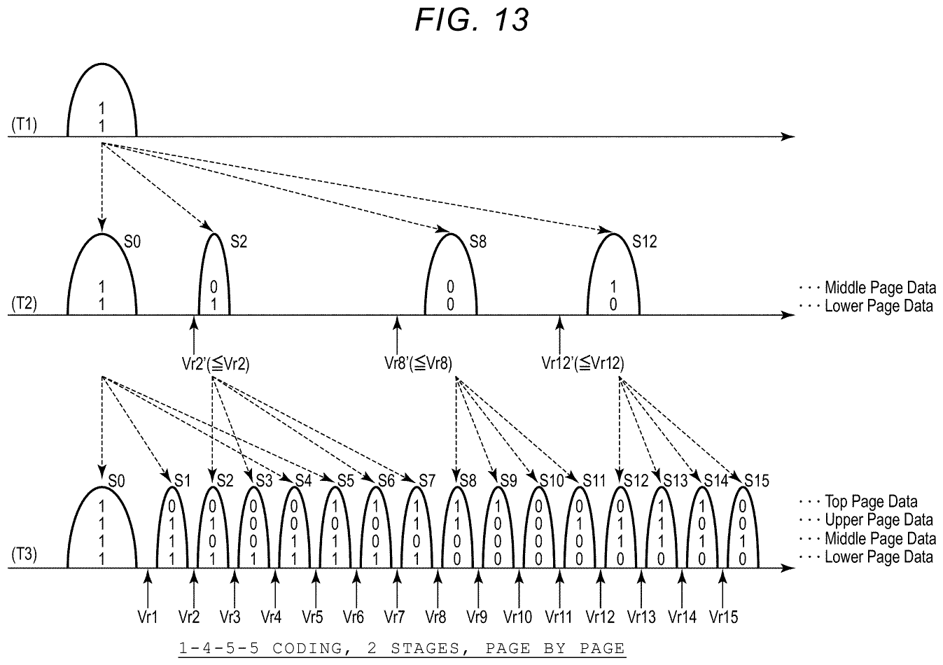

Next, an MLC-fine program operation that is a second writing scheme in the 2-step write operation will be described with reference to FIG. 13.

FIG. 13 is a diagram illustrating a change in a threshold voltage distribution of the memory cell MC in the second writing scheme in the memory system 3 according to the embodiment.

FIG. 13 illustrates a threshold voltage distribution after execution of the first-step program operation and a threshold voltage distribution after execution of the second-step program operation on the memory cell MC.

When the MLC-fine program operation that is the second writing scheme is executed, the NAND flash memory 5 executes an MLC program operation of writing 2-bit data per memory cell MC as the first-step program operation. The NAND flash memory 5 executes the fine program operation of writing 4-bit data per memory cell MC as the second-step program operation.

T1 of FIG. 13 indicates a threshold voltage distribution corresponding to an erased state that is an initial state before the program operation is executed. T2 of FIG. 13 indicates a threshold voltage distribution after the MLC program operation that is the first-step program operation is executed. T3 of FIG. 13 indicates a threshold voltage distribution after the fine program operation that is the second-step program operation is executed.

As indicated by T1 of FIG. 13, all the memory cells of the memory cell array 52 in the initial state have the threshold voltage included in the threshold voltage distribution Er corresponding to an unwritten state (erased state).

As indicated by T2 of FIG. 13, the control unit 51 of the NAND flash memory 5 maintains each memory cell MC as the threshold voltage distribution Er or transitions each memory cell MC to another threshold voltage distribution higher than the threshold voltage distribution Er in the first-step program operation according to bit values to be written into the lower page and the middle page.

Specifically, when the bit values to be written into the lower page and the middle page are “11”, the control unit 51 maintains a threshold voltage distribution S0 corresponding to the erased state. When the bit values to be written into at least one of the lower page and the middle page are “0”, the control unit 51 causes the threshold voltage of the writing destination memory cell MC to transition to a higher side. That is, when the bit values to be written into the lower page and the middle page are “01”, the control unit 51 causes the writing destination memory cell MC to transition to a threshold voltage distribution S2. When the bit values to be written into the lower page and the middle page are “00”, the control unit 51 causes the writing destination memory cell MC to transition to a threshold voltage distribution S8. When the bit values to be written into the lower page and the middle page are “10”, the control unit 51 the writing destination memory cell MC to transition to a threshold voltage distribution S12.

Here, the threshold voltage distributions S8 and S12 may be coarsely programmed by widening the width of a threshold voltage region such that the threshold voltage is slightly lowered. This is because the threshold voltage distribution can transition by the fine program operation that is the second-step program in the end even when an interval between adjacent threshold regions is widened in a step in which the MLC program operation that is the first-step program operation is executed.

Accordingly, the memory cell is programmed to a four-valued state according to data of the lower page and the middle page. Here, data writing in the MLC program operation (the first-step program operation) is a program operation of writing only lower-page data and middle-page data. Therefore, data necessary to execute the MLC program operation is only the lower-page data and the middle-page data. A threshold voltage distribution after execution of the MLC program operation transitions again by the fine program operation that is the second-step program operation executed subsequently. Therefore, when the MLC program operation is executed, it is not necessary to finely shape the threshold voltage distribution, which enables high-speed programming. The lower-page data and the middle-page data can be read from the memory cell after the MLC program operation is executed.

As indicated by T3 of FIG. 13, to execute writing of data in the fine program operation that is the second-step program operation, data corresponding to two pages including upper-page data and top-page data is necessary. The NAND flash memory 5 executes a program operation to separate 16 threshold voltage distributions in the end after the fine program operation is executed. Here, all pieces of page data can be read.

When the fine program operation is executed, the larger a change in the threshold voltage of the memory cell MC from the threshold voltage distribution after execution of the first-step program operation is, the greater an inter-cell interference is. Accordingly, when the threshold voltage distribution of the MLC program operation is changed to the threshold voltage distribution of the fine program operation, a maximum change is preferably as small as possible. In the example of FIG. 13, the maximum change in the threshold voltage distribution is equivalent to five threshold voltage distributions and appears when the threshold voltage distribution S0 is changed to S5 and the threshold voltage distribution S2 is changed to S7.

In general, writing (program operation) on the memory cell is executed by applying a program voltage pulse on a corresponding word line once or a plurality of times. After each program voltage pulse is applied, reading is executed to check whether the memory cell transitioned beyond a threshold boundary level. By repeating application and reading of the program voltage pulse, the threshold voltage of the memory cell can be moved to a threshold voltage region having a predetermined threshold voltage distribution.

More specifically, when writing of a plurality of pages is executed as in the fine program operation, a threshold voltage of a corresponding memory cell is determined from data of all the writing target pages (here, the lower page, the middle page, the upper page, and the top page), and writing is executed while a voltage value of the plurality of program pulses is gradually raised to reach the determined threshold voltage. The memory cell MC that reached a target threshold voltage is excluded from a writing target. As such, the writing on the memory cell is not performed page by page but is collectively performed for all the writing target pages.

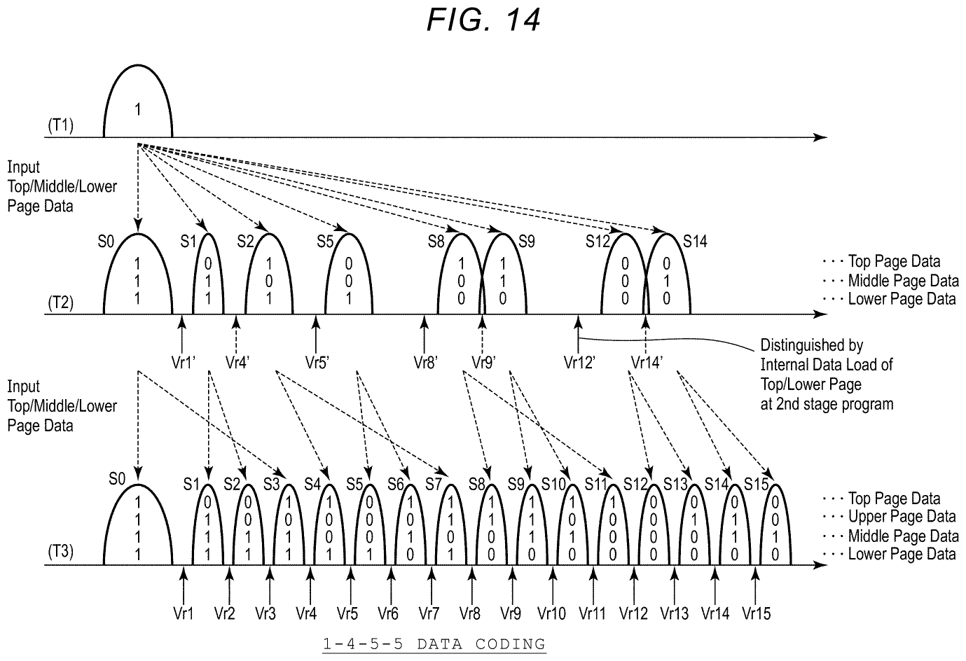

Next, a TLC-fine program that is a third writing scheme in the 2-step write operation will be described with reference to FIG. 14.

FIG. 14 is a diagram illustrating a change in a threshold voltage distribution of the memory cell MC in the third writing scheme in the memory system 3 according to the embodiment.

FIG. 14 illustrates a threshold voltage distribution after execution of the first-step program operation and a threshold voltage distribution after execution of the second-step program operation on the memory cell MC.

When the TLC-fine program operation that is the third writing scheme is executed, the NAND flash memory 5 executes the TLC program operation of writing 3-bit data per memory cell MC as the first-step program operation. The NAND flash memory 5 executes the fine program operation of writing 4-bit data per memory cell MC as the second-step program operation.

T1 of FIG. 14 indicates a threshold voltage distribution corresponding to an erased state that is an initial state before the program operation is executed. T2 of FIG. 14 indicates a threshold voltage distribution after the TLC program operation that is the first-step program operation is executed. T3 of FIG. 14 indicates a threshold voltage distribution after the fine program operation that is the second-step program operation is executed.

As indicated by T1 of FIG. 14, all the memory cells of the memory cell array 52 in the initial state have the threshold voltage included in the threshold voltage distribution S0 corresponding to an unwritten state (erased state).

As indicated by T2 of FIG. 14, the control unit 51 of the NAND flash memory 5 maintains each memory cell MC as the threshold voltage distribution S0 or causes each memory cell MC to transition to another threshold voltage distribution higher than the threshold voltage distribution S0 according to bit values to be written into the lower page, the middle page, and the top page.

Specifically, the control unit 51 executes a program operation such that charges are not injected when bit values to be written into the lower page, the middle page, and the top page are all “1”, and such that the threshold voltage of the writing destination memory cell MC transitions to a state higher than the threshold voltage distribution corresponding to the erased state when any of the bit values to be written into the lower page, the middle page, and the top page is “0”.

That is, when the bit values to be written into the lower page, the middle page, and the top page are “111”, the control unit 51 maintains the threshold voltage distribution S0 corresponding to the erased state. When the bit values to be written into the lower page, the middle page, and the top page are “011”, the control unit 51 causes the writing destination memory cell MC to transition to the threshold voltage distribution S1. When the bit values to be written into the lower page, the middle page, and the top page are “101”, the control unit 51 causes the writing destination memory cell MC to transition to the threshold voltage distribution S4. When the bit values to be written into the lower page, the middle page, and the top page are “001”, the control unit 51 transitions the writing destination memory cell MC to the threshold voltage distribution S5. When the bit values to be written into the lower page, the middle page, and the top page are “100”, the control unit 51 causes the writing destination memory cell MC to transition to the threshold voltage distribution S8. When the bit values to be written into the lower page, the middle page, and the top page are “110”, the control unit 51 causes the writing destination memory cell MC to transition to the threshold voltage distribution S9. When the bit values to be written into the lower page, the middle page, and the top page are “000”, the control unit 51 causes the writing destination memory cell MC to transition to the threshold voltage distribution S12. When the bit values to be written into the lower page, the middle page, and the top page are “010”, the control unit 51 causes the writing destination memory cell MC to transition to the threshold voltage distribution S14.

Here, preferably, the distributions S1, S4, S5, S8, S9, S12, and S14 are coarsely programmed by widening the width of a threshold voltage region such that the threshold voltage is slightly lowered. Accordingly, it is possible to shorten a time required for programming. This is because the threshold voltage distribution can transition by the fine program operation that is the second-step program in the end even when an interval between adjacent threshold regions is widened in a step in which the TLC program operation that is the first-step program operation is executed.

Preferably, an interval between the adjacent threshold voltage distributions S8 and S9 and an interval between the adjacent threshold voltage distributions S12 and S14 are narrower than intervals between other adjacent distributions. Bit values to be written of the adjacent threshold voltage distributions of which the interval is narrowed differ in the middle-page data. That is, the data after the TLC program that is the first-step program operation appears as binary, such that the lower page, the middle page, and the top page can be read. However, by narrowing the interval between the threshold voltage distributions in which the data of the middle page is different, it is possible to ensure a large interval between the threshold voltage distributions in which the data of the lower page and the top page is different, and thus a margin in reading of the lower page and the top page is increased.

Subsequently, as indicated by T3 of FIG. 14, in the fine program operation that is the second-step program operation, two pages of the middle page and the upper page is necessary for writing data. The control unit 51 of the NAND flash memory 5 programs the threshold voltage distribution after the fine program operation that is the second-step program operation such that a 16-valued state is obtained in the final state in which each of the adjacent distributions is separated. After the fine program operation is executed, data of all the pages can be read.

In the fine program operation that is the second-step program operation, the larger a change in a threshold voltage of the memory cell MC from a threshold voltage at the end of the TLC program operation is, the greater an inter-cell interference is. Accordingly, a change in the threshold voltage distribution in which a threshold voltage distribution of the memory cells is the largest is preferably minimum. According to the embodiment, a maximum change in the threshold voltage distribution is equivalent to three threshold voltage distributions and is made when the threshold voltage distribution S0 is changed to S3, the threshold voltage distribution S4 is changed to S7, and the threshold voltage distribution S8 is changed to S11.

In general, the program operation is executed by applying a program voltage pulse once or a plurality of times. When applying the program voltage pulse a plurality of times, a voltage value rises gradually. After each program voltage pulse is applied, reading referred to as verification is executed to confirm whether the memory cell transitioned beyond a threshold boundary level. By repeating application and reading of the program voltage pulse, the threshold voltage of the memory cell can be moved into a range of a predetermined threshold voltage distribution.

Next, a writing order on a plurality of memory cells in a writing destination block will be described.

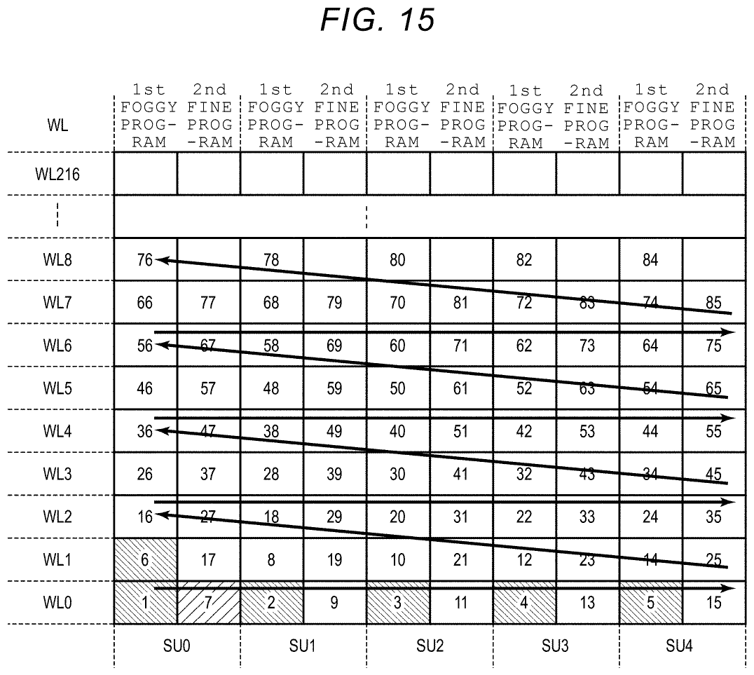

First, a writing order according to a first comparative example will be described with reference to FIG. 15. FIG. 15 is a diagram illustrating an example of a writing order of a 2-step write operation according to the first comparative example.

In the first comparative example, the memory controller instructs the NAND flash memory to execute the foggy-fine program operation that is the first writing scheme. The memory controller designates writing destination memory cells in string-major order in the writing destination block. In the writing order in string-major order, the memory controller executes the first-step program operation on the plurality of memory cells connected to the same word line, and then executes the first-step program operation on memory cells connected to a subsequent word line.

In FIGS. 15 to 21, a number written in a storage position corresponding to each memory cell indicates an order of a program operation in a writing destination block.

Hereinafter, for simplicity, the memory cell connected to a word line WL A and belonging to a string unit SU B is indicated as a storage position (A, B).

Specifically, the memory controller first executes the foggy program operation that is the first-step program operation on a storage position (0, 0). The memory controller executes the foggy program operation that is the first-step program operation on a storage position (0, 1). The memory controller executes the foggy program operation that is the first-step program operation on a storage position (0, 2). The memory controller executes the foggy program operation that is the first-step program operation on a storage position (0, 3). The memory controller executes the foggy program operation that is the first-step program operation on a storage position (0, 4). Accordingly, the memory controller completes the foggy program operation on the plurality of memory cells connected to the word line WL0.

Then, the memory controller executes the foggy program operation that is the first-step program operation on a storage position (1, 0). That is, in response to completion of the foggy program operation on the memory cells connected to WL0, the memory controller starts the foggy program operation on the memory cells connected to WL1.

Then, in response to completion of the foggy program operation on the storage position (1, 0), the memory controller executes the fine program operation that is the second-step program operation on the storage position (0, 0). That is, in response to the completion of the foggy program operation on the memory cell belonging to the same string unit and connected to a subsequent word line, the memory controller executes the fine program operation.

As such, from execution of the foggy program operation on the storage position (0, 0) until execution of the fine program operation on the storage position (0, 0), the foggy program operation is executed on six storage positions including the storage position (0, 0). Here, the memory controller is required to store data to be written into each storage position until the fine program operation is executed on each storage position. That is, when data corresponding to four pages is written into each of the six storage positions by QLC writing, a buffer capable of storing data corresponding to 6×4 pages is required for the memory controller. When unexpected shutdown occurs without notification from the host, the memory controller is required to write temporarily stored data into the NAND flash memory using emergency power. Therefore, the larger the size of data of which foggy program operation is executed but the fine program operation is not yet executed is, the larger the capacity of the required emergency power is.

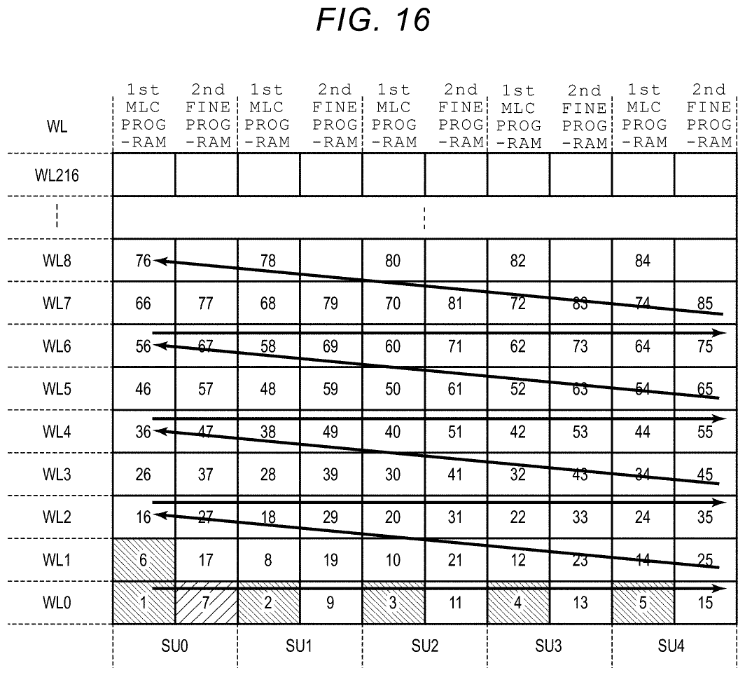

Next, a writing order according to a second comparative example will be described with reference to FIG. 16. FIG. 16 is a diagram illustrating an example of a writing order of a 2-step write operation according to the second comparative example.

In the second comparative example, the memory controller instructs the NAND flash memory to execute the MLC-fine program operation that is the second writing scheme. The memory controller designates writing destination memory cells in string-major order in the writing destination block. That is, the memory controller executes the program operation on each memory cell in the writing destination block in the same order as that of the first comparative example. However, as the MLC-fine program operation is executed, the memory controller writes 2-bit data on each memory cell by the MLC program operation that is the first-step program operation.

Specifically, the memory controller first executes the MLC program operation that is the first-step program operation on the storage position (0, 0). The memory controller executes the MLC program operation that is the first-step program operation on the storage position (0, 1). The memory controller executes the MLC program operation that is the first-step program operation on the storage position (0, 2). The memory controller executes the MLC program operation that is the first-step program operation on the storage position (0, 3). The memory controller executes the MLC program operation that is the first-step program operation on the storage position (0, 4). Accordingly, the memory controller completes the MLC program operation on the plurality of memory cells connected to the word line WL0.

Then, the memory controller executes the MLC program operation that is the first-step program operation on the storage position (1, 0). That is, in response to completion of the MLC program operation on the memory cells connected to WL0, the memory controller starts the MLC program operation on the memory cells connected to WL1.

Then, in response to completion of the MLC program operation on the storage position (1, 0), the memory controller executes the fine program operation that is the second-step program operation on the storage position (0, 0). That is, in response to the completion of the MLC program operation on the memory cell belonging to the same string unit and connected to a subsequent word line, the memory controller executes the fine program operation.

As such, from execution of the MLC program operation on the storage position (0, 0) until execution of the fine program operation on the storage position (0, 0), the MLC program operation is executed on six storage positions including the storage position (0, 0). Here, the memory controller is required to store data not yet written by the MLC program operation among data to be written into each storage position until the fine program operation is executed on each storage position. That is, when data corresponding to four pages is written into each of the six storage positions by QLC writing, data corresponding to two pages are already written by the MLC program operation, and thus a buffer that stores data corresponding to 6×(4−2) pages is required for the memory controller. By executing not the foggy-fine program operation but the MLC-fine program operation, in the second comparative example, it is possible to further reduce an amount of stored data than in the first comparative example.

Here, in the MLC-fine program operation, there is a disadvantage that reliability of data deteriorates than in the foggy-fine program operation. This is because, as described in FIG. 13, the maximum change in the threshold voltage distribution transitioning in the fine program operation of the MLC-fine program operation is greater than the change in the threshold voltage distribution transitioning in the fine program operation of the foggy-fine program operation.

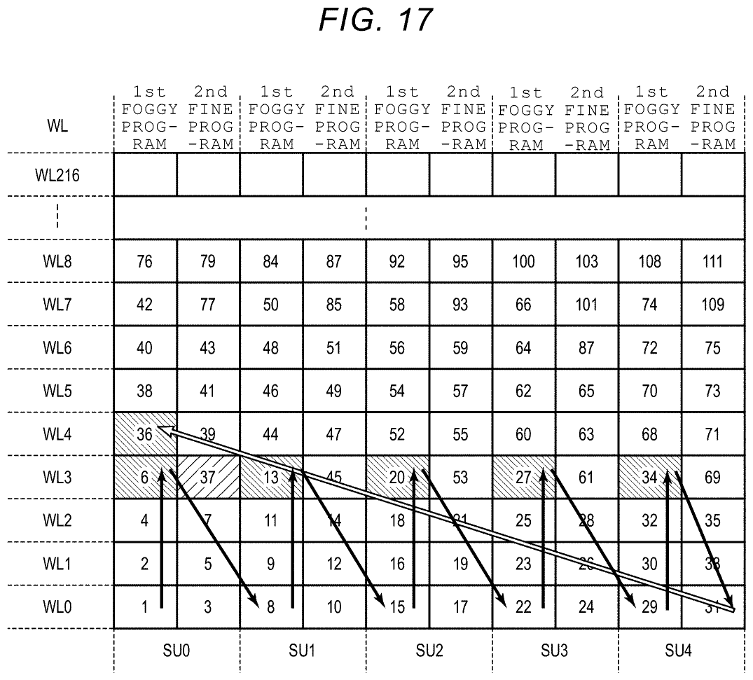

Next, a writing order according to a third comparative example will be described with reference to FIG. 17. FIG. 17 is a diagram illustrating an example of a writing order of a 2-step write operation according to the third comparative example.

In the third comparative example, the memory controller instructs the NAND flash memory to execute the foggy-fine program operation that is the first writing scheme. The memory controller designates writing destination memory cells in word line-major order in the writing destination block. In the writing order in word line-major order, the memory controller executes the foggy-fine program operation by setting a certain string unit as a writing destination until the fine program operation is executed on memory cells connected to N word lines among the memory cells belonging to the string unit. Thereafter, the memory controller changes the writing destination to a subsequent string unit. Here, N is the number of word lines bundled in word line-major order. N is an integer of 1 or more and less than the number of word lines in the writing destination block. Here, the word line that is a multiple of N+1 is referred to as a boundary word line.

FIG. 17 illustrates an instance in which N is 3. That is, fourth, eighth, . . . word lines are the boundary word lines.

Specifically, the memory controller first executes the foggy program operation that is the first-step program operation on the storage position (0, 0). The memory controller executes the foggy program operation that is the first-step program operation on the storage position (1, 0). Then, in response to completion of the foggy program operation on the storage position (1, 0), the memory controller executes the fine program operation that is the second-step program operation on the storage position (0, 0). That is, in response to the completion of the foggy program operation on the memory cell belonging to the same string unit and connected to a subsequent word line, the memory controller executes the fine program operation.

Here, from execution of the foggy program operation on the storage position (0, 0) until execution of the fine program operation on the storage position (0, 0), the foggy program operation is executed on only the storage positions (0, 0) and (1, 0). Therefore, the memory controller is required to store data to be written into two storage positions. That is, when data corresponding to four pages is written into each of the two storage positions by QLC writing, a buffer that stores data corresponding to 2×4 pages is required for the memory controller.

Thereafter, the memory controller executes the foggy program operation that is the first-step program operation on a storage position (2, 0). The memory controller executes the fine program operation that is the second-step program operation on the storage position (1, 0).

The memory controller executes the foggy program operation that is the first-step program operation on a storage position (3, 0). The memory controller executes the fine program operation that is the second-step program operation on the storage position (2, 0).

Here, the memory controller changes a writing destination string unit to the string unit SU1 in response to completion of the foggy program operation on the storage position (3, 0) connected to the word line WL3 that is a boundary word line and completion of the fine program operation on the storage position (2, 0) which can be executed after completion of the foggy program operation on the storage position (3, 0). The memory controller executes the foggy program operation that is the first-step program operation on the storage position (0, 1).

As such, when the program operation is executed up to the memory cells connected to the boundary word line among the memory cells belonging to each string unit, the memory controller writes data into the memory cells connected to a word line subsequent to the boundary word line.

Thereafter, the program operation progresses, and when the fine program operation on a storage position (2, 4) is completed, the memory controller executes the foggy program operation on a storage position (4, 0). Then, the memory controller executes the fine program operation on the storage position (3, 0) connected to the boundary word line.

As such, at a timing at which the fine program operation is executed on the storage position (3, 0), only the foggy program operation is being executed and the storage positions on which the fine program operation is not yet executed are storage positions (3, 0), (4, 0), (3, 1), (3, 2), (3, 3), and (3, 4). That is, when data corresponding to four pages is written into each memory cell by QLC writing, a buffer that stores data corresponding to 6×4 pages is required for the memory controller.

Accordingly, in the writing order in word line-major order in the third comparative example, there is a position such as the storage position (0, 0) for which an amount of data to be stored can be reduced compared to the first comparative example. However, focusing on the memory cells connected to the boundary word lines such as the storage position (3, 0), an amount of data to be stored in the third comparative example is equal to that of the first comparative example.

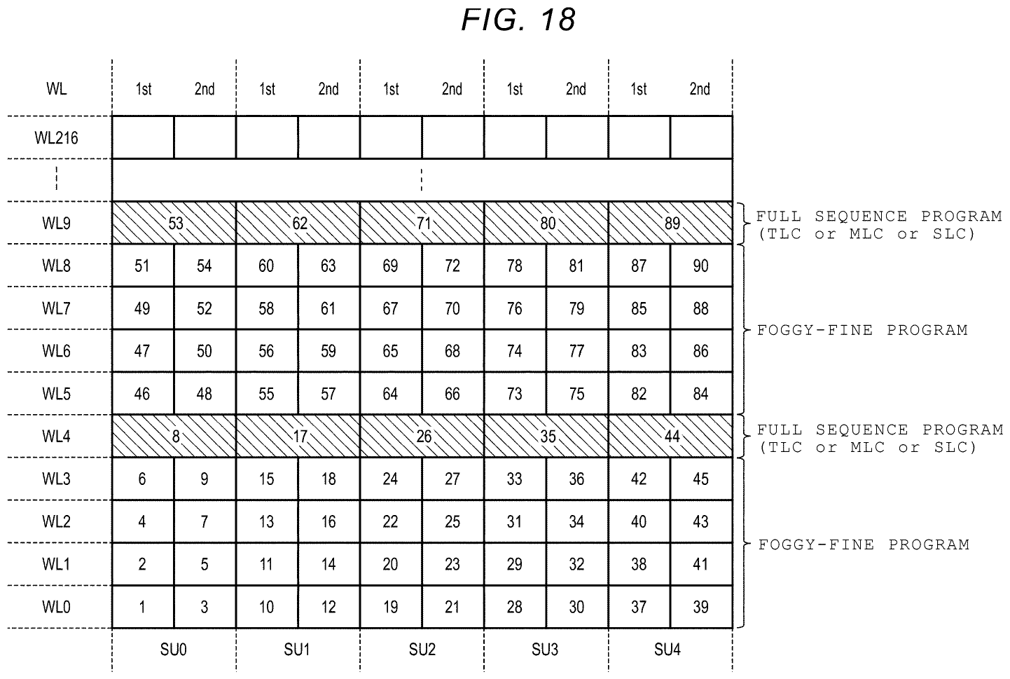

Next, a program operation according to a fourth comparative example will be described with reference to FIG. 18. FIG. 18 is a diagram illustrating an example of a writing order of a 1-step write operation and a 2-step write operation according to the fourth comparative example.

In the fourth comparative example, the memory controller instructs the NAND flash memory to execute the 1-step program operation on the memory cells connected to the boundary word lines. The memory controller instructs the NAND flash memory to execute the 2-step write program operation on the memory cells connected to the word lines other than the boundary word lines. The memory controller designates writing destination memory cells in word line-major order in the writing destination block.

FIG. 18 illustrates an instance in which N is 4. That is, fifth, tenth, . . . word lines are the boundary word lines.

In FIG. 18, the foggy-fine program operation is executed as the 2-step write operation and a full sequence program operation is executed as the 1-step write operation. In the full sequence program operation, the memory controller executes any of the TLC program operation, the MLC program operation, or the SLC program operation on the memory cells connected to the boundary word lines. Therefore, 3-bit data, 2-bit data, or 1-bit data is stored in the memory cells connected to the boundary word lines. Here, it is assumed that the memory controller executes the TLC program operation as the full sequence program operation.

Specifically, the memory controller first executes the foggy program operation that is the first-step program operation on the storage position (0, 0). The memory controller executes the foggy program operation that is the first-step program operation on the storage position (1, 0). Then, in response to completion of the foggy program operation on the storage position (1, 0), the memory controller executes the fine program operation that is the second-step program operation on the storage position (0, 0). That is, in response to the completion of the foggy program operation on the memory cell belonging to the same string unit and connected to a subsequent word line, the memory controller executes the fine program operation.

Then, the memory controller executes the foggy program operation that is the first-step program operation on the storage position (2, 0). The memory controller executes the fine program operation that is the second-step program operation on the storage position (1, 0).

The memory controller executes the foggy program operation that is the first-step program operation on the storage position (3, 0). Then, the memory controller executes the fine program operation that is the second-step program operation on the storage position (2, 0) connected to WL2 and belonging to the string unit SU0.

Then, the memory controller executes the full sequence program operation that is the 1-step write operation on the storage position (4, 0) connected to the word line WL4 that is the boundary word line. That is, the memory controller writes 3-bit data on the storage position (4, 0) by the full sequence program operation.

In response to completion of the full sequence program operation on the storage position (4, 0), the memory controller executes the fine program operation that is the second-step program on the storage position (3, 0).

In response to completion of the fine program operation on the storage position (3, 0), the memory controller changes the writing destination string unit to the string unit SU1. Then, the memory controller executes the foggy program operation that is the first-step program operation on the storage position (0, 1).

Thereafter, the program operation progresses, and when the full sequence program operation on a storage position (4, 4) and the fine program operation on a storage position (3, 4) are completed, the memory controller executes the foggy program operation on a storage position (5, 0) connected to the word line WL5 subsequent to the word line WL4 that is the boundary word line.

As such, unlike the third comparative example, in the fourth comparative example, the full sequence program operation is executed on the memory cells connected to the boundary word lines. Therefore, it is not necessary for the memory controller to store data to be written into the memory cells connected to the boundary word lines for a long time. Specifically, at a timing at which the foggy program operation is executed on the storage position (5, 0), the memory cell on which only the foggy program operation is executed is only the storage position (5, 0). Accordingly, in the fourth comparative example, a maximum value of a data size required to be stored on the memory controller can be further reduced than in the third comparative example.

Here, the full sequence program operation executed on the memory cells connected to the boundary word lines is any of the SLC program operation, the MLC program operation, or the TLC program operation. Therefore, in the memory cells connected to the boundary word lines, data to be written per memory cell is 1 to 3 bits. Therefore, a storage capacity of the memory system is further reduced than when 4-bit data per memory cell is written on each memory cell.

For example, when four word lines are bundled in word line-major order (N=4), the program operation on ⅕ of the memory cells is the TLC program operation. Therefore, a maximum capacity of the memory system is lost by 0.5%. When nine word lines are bundled (N=9), the program operation on 1/10 of the memory cells is the TLC program operation. Therefore, a maximum capacity of the memory system is lost by 0.25%. When the full sequence program operation on the memory cells connected to the boundary word lines is the MLC program operation or the SLC program operation, a loss amount further increases.

Meanwhile, in the memory system 3 according to the embodiment, the MLC-fine program operation or the TLC-fine program operation is executed on the memory cells connected to the boundary word lines.

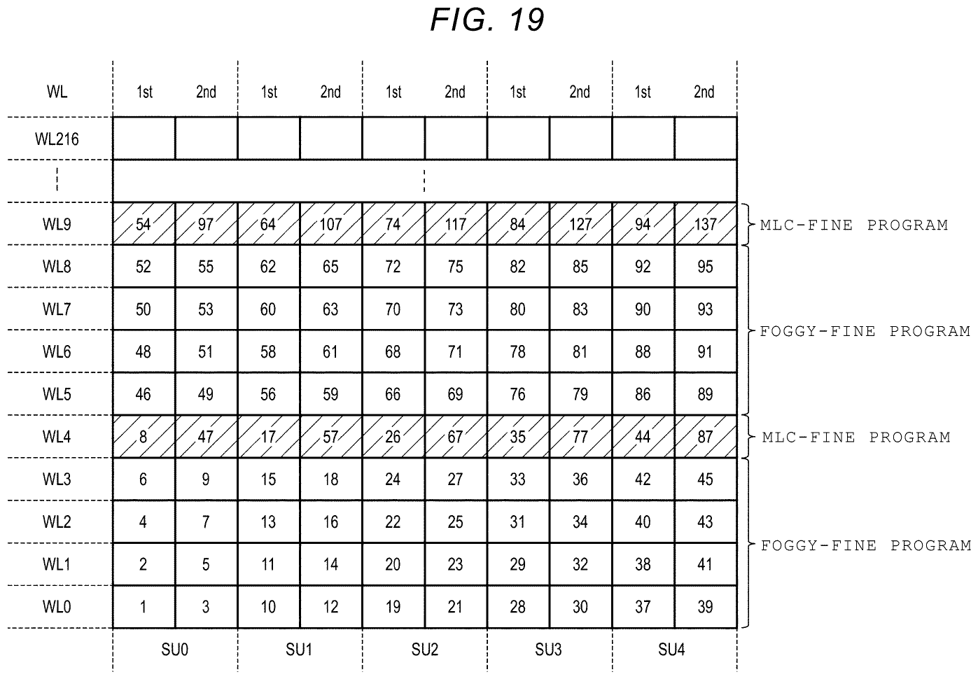

The 2-step write operation executed in the memory system 3 according to the embodiment will be described with reference to FIG. 19. FIG. 19 is a diagram illustrating a first example of a writing order of the 2-step write operation according to the embodiment.

In the first example, the memory controller 4 instructs the NAND flash memory 5 to execute the MLC-fine program operation that is the 2-step write operation on the memory cells connected to the boundary word lines. The memory controller 4 instructs the NAND flash memory 5 to execute the foggy-fine program operation that is the 2-step write operation on the memory cells connected to the word lines other than the boundary word lines. The memory controller 4 designates writing destination memory cells in word line-major order in the writing destination block.

FIG. 19 illustrates an instance in which N is 4. That is, fifth, tenth, . . . word lines are the boundary word lines.

Specifically, the memory controller 4 first executes the foggy program operation that is the first-step program operation on the storage position (0, 0). The memory controller 4 executes the foggy program operation that is the first-step program operation on the storage position (1, 0). Then, the memory controller 4 executes the fine program operation that is the second-step program operation on the storage position (0, 0). That is, in response to the completion of the foggy program operation on the memory cell belonging to the same string unit and connected to a subsequent word line, the memory controller 4 executes the fine program operation.

Then, the memory controller 4 executes the foggy program operation that is the first-step program operation on the storage position (2, 0). The memory controller 4 executes the fine program operation that is the second-step program operation on the storage position (1, 0).

The memory controller 4 executes the foggy program operation that is the first-step program operation on the storage position (3, 0). Then, the memory controller 4 executes the fine program operation that is the second-step program operation on the storage position (2, 0).

The memory controller 4 executes the MLC program operation that is the first-step write operation on the storage position (4, 0) connected to the word line WL4 that is the boundary word line. That is, the memory controller 4 writes 2-bit data on the storage position (4, 0) by the MLC program operation.

After the MLC program operation on the storage position (4, 0) is executed, the memory controller 4 executes the fine program operation that is the second-step program on the storage position (3, 0).

In response to completion of the fine program operation on the storage position (3, 0), the memory controller 4 changes the writing destination string unit to the string unit SU1. Then, the memory controller 4 executes the foggy program operation that is the first-step program operation on the storage position (0, 1).

Thereafter, the program operation progresses, and when the MLC program operation on the storage position (4, 4) and the fine program operation on the storage position (3, 4) are completed, the memory controller 4 executes the foggy program operation that is the first-step program operation on the storage position (5, 0) connected to the word line WL5 subsequent to the word line WL4 that is the boundary word line. Then, the memory controller 4 executes the fine program operation that is the second-step program operation on the storage position (4, 0) connected to the word line WL4 that is the boundary word line.

Here, the memory controller 4 executes the fine program operation that is the second-step program operation using 2-bit data written in the first-step program operation. The memory controller 4 uses any schemes of internal data loading (IDL) or external data loading (EDL).

When the IDL is used, the memory controller 4 transmits additional 2-bit data (for example, the top-page data and the upper-page data) to the NAND flash memory 5. The NAND flash memory 5 reads 2-bit data written in advance (for example, the middle-page data and the lower-page data). The NAND flash memory 5 determines a target threshold voltage distribution based on the read 2-bit data and the received additional 2-bit data. The NAND flash memory 5 executes the fine program operation based on the determined threshold voltage distribution.

When the EDL is used, the memory controller 4 reads 2-bit data written in advance (for example, the middle-page data and the lower-page data) from the NAND flash memory 5. The memory controller 4 generates 4-bit data obtained by combining the read 2-bit data and additional 2-bit data (for example, the top-page data and the upper-page data) and instructs the NAND flash memory 5 to execute the fine program operation based on the generated 4-bit data.

Accordingly, the memory controller 4 only needs to store at least additional 2-bit data (for example, the top-page data and the upper-page data) until the fine program operation is executed on the memory cells connected to the boundary word lines.

At a timing at which the fine program operation is executed on the storage position (4, 0), the memory cells on which only the first-step program operation is executed and the fine program operation is not yet executed are storage positions (4, 0), (5, 0), (4, 1), (4, 2), (4, 3), and (4, 4). Among the six storage positions, all the storage positions other than the storage position (5, 0) are memory cells in which 2-bit data is written by the MLC program operation. That is, in the memory controller 4, a buffer that stores data to be written into each memory cell is required, in which the data corresponds to 5×2 pages+1×4 pages. Therefore, the required size of the buffer and a capacity required for the capacitor 62 can be further reduced than in the first and third comparative examples.

In all the memory cells connected to the boundary word lines according to the embodiment, 4-bit data is written in the end. Therefore, loss of the maximum capacity of the memory system 3 as in the fourth comparative example does not occur.

Accordingly, it is possible to prevent loss of the maximum capacity of the memory system 3 from occurring while reducing an amount of data required to be stored in the memory controller 4.

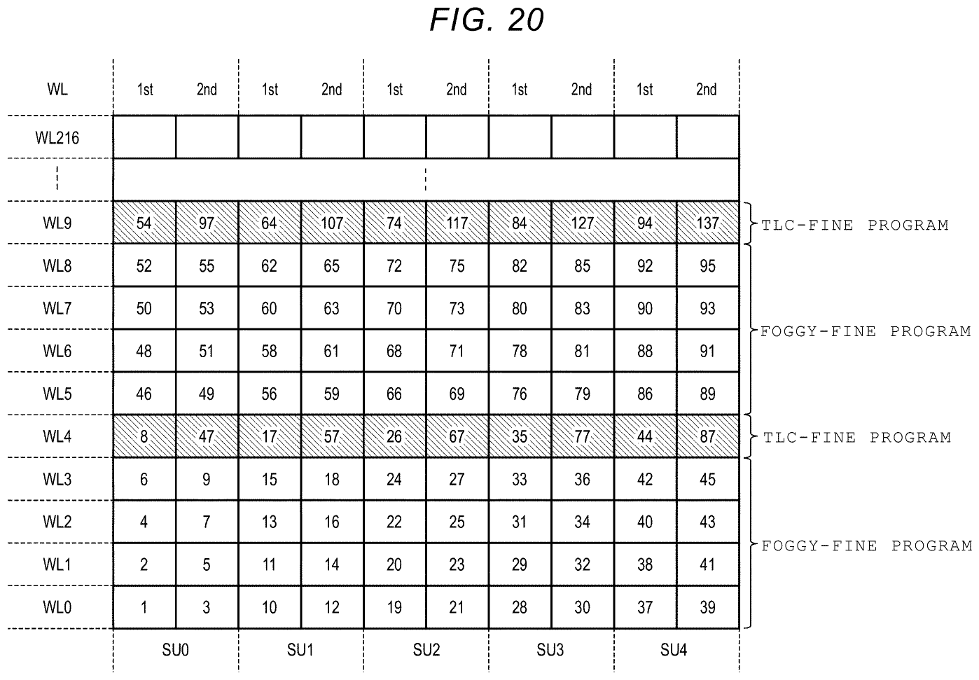

Next, the 2-step write operation executed in the memory system 3 according to the embodiment will be described with reference to FIG. 20. FIG. 20 is a diagram illustrating a second example of the writing order of the 2-step write operation according to the embodiment.

In the second example, the memory controller 4 instructs the NAND flash memory 5 to execute the TLC-fine program operation that is the 2-step write operation on the memory cells connected to the boundary word lines. The memory controller 4 instructs the NAND flash memory 5 to execute the foggy-fine program operation that is the 2-step write operation on the memory cells connected to the word lines other than the boundary word lines. The memory controller 4 designates writing destination memory cells in word line-major order in the writing destination block.

FIG. 20 illustrates an instance in which N is 4. That is, fifth, tenth, . . . word lines are the boundary word lines.

Specifically, the memory controller 4 first executes the foggy program operation that is the first-step program operation on the storage position (0, 0). The memory controller 4 executes the foggy program operation that is the first-step program operation on the storage position (1, 0). Then, the memory controller 4 executes the fine program operation that is the second-step program operation on the storage position (0, 0). That is, in response to completion of the foggy program operation on the memory cell belonging to the same string unit and connected to a subsequent word line, the memory controller 4 executes the fine program operation.

Then, the memory controller 4 executes the foggy program operation that is the first-step program operation on the storage position (2, 0). The memory controller 4 executes the fine program operation that is the second-step program operation on the storage position (1, 0).

The memory controller 4 executes the foggy program operation that is the first-step program operation on the storage position (3, 0). Then, the memory controller 4 executes the fine program operation that is the second-step program operation on the storage position (2, 0).

The memory controller 4 executes the TLC program operation that is the first-step write operation on the storage position (4, 0) connected to the word line WL4 that is the boundary word line. That is, the memory controller 4 writes 3-bit data on the storage position (4, 0) by the TLC program operation.

After the TLC program operation on the storage position (4, 0) is executed, the memory controller 4 executes the fine program operation that is the second-step program on the storage position (3, 0).

In response to completion of the fine program operation on the storage position (3, 0), the memory controller 4 changes the writing destination string unit to the string unit SU1. Then, the memory controller 4 executes the foggy program operation that is the first-step program operation on the storage position (0, 1).

Thereafter, the program operation progresses, and when the TLC program operation on the storage position (4, 4) and the fine program operation on the storage position (3, 4) are completed, the memory controller 4 executes the foggy program operation that is the first-step program operation on the storage position (5, 0) connected to the word line WL5 subsequent to the word line WL4 that is the boundary word line. Then, the memory controller 4 executes the fine program operation that is the second-step program operation on the storage position (4, 0) connected to the word line WL4 that is the boundary word line.

Here, the memory controller 4 executes the fine program operation that is the second-step program operation using 3-bit data written in the first-step program operation. The memory controller 4 uses, for example, the EDL. Here, the memory controller 4 reads the 3-bit data written in advance (for example, the top-page data, the middle-page data, and the lower-page data) from the NAND flash memory 5. The ECC circuit 45 of the memory controller 4 executes error correction. The memory controller 4 generates 4-bit data by combining the 3-bit data subjected to the error correction and additional 1-bit data (for example, the upper-page data) and instructs the NAND flash memory 5 to execute the fine program operation based on the generated 4-bit data.

Accordingly, the memory controller 4 only needs to store at least additional 1-bit data (for example, the upper-page data) until the fine program operation is executed on the memory cells connected to the boundary word lines.

At a timing at which the fine program operation is executed on the storage position (4, 4), the memory cells on which only the first-step program operation is executed and the fine program operation is not yet executed are the storage positions (4, 0), (5, 0), (4, 1), (4, 2), (4, 3), and (4, 4). Among the six storage positions, all the storage positions other than the storage position (5, 0) are memory cells in which 3-bit data is written by the TLC program operation. That is, in the memory controller 4, a buffer that stores data to be written into each memory cell is required, in which the data corresponds to 5×1 pages+1×4 pages. Therefore, the required size of the buffer and a capacity required for the capacitor 62 can be further reduced than in the first and third comparative examples.

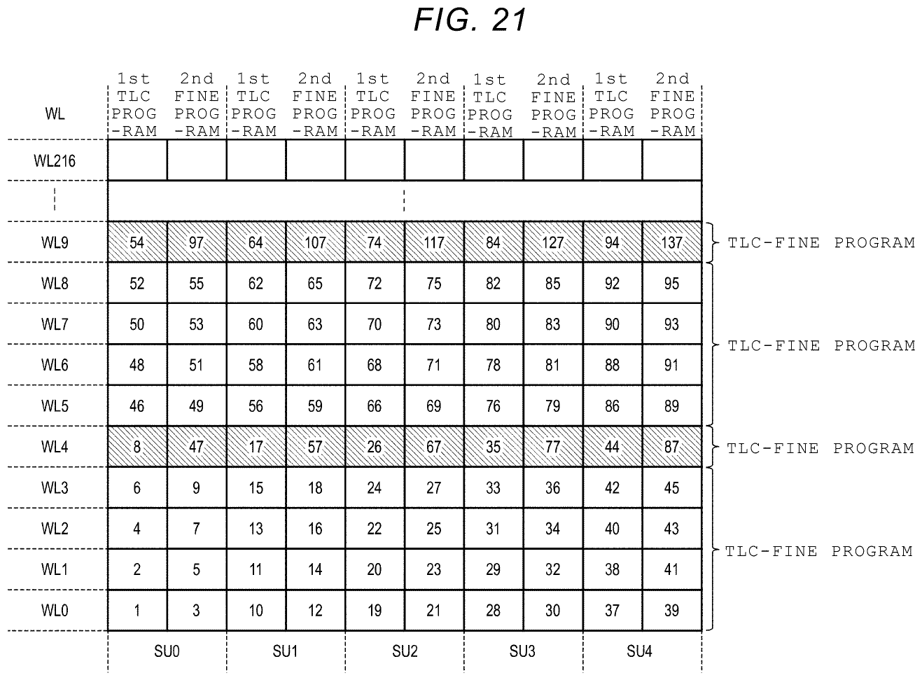

Here, a program operation on the memory cells connected to the word lines other than the boundary word lines when the TLC-fine program operation is executed will be described with reference to FIG. 21. FIG. 21 is a diagram illustrating a third example of the writing order of the 2-step write operation according to the embodiment.

In the third example, the memory controller 4 instructs the NAND flash memory 5 to execute the TLC-fine program operation that is the 2-step write operation on the memory cells connected to the boundary word lines. The memory controller 4 instructs the NAND flash memory 5 to execute the TLC-fine program operation that is the 2-step write operation also on the memory cells connected to the word lines other than the boundary word lines. The memory controller 4 designates writing destination memory cells in word line-major order in the writing destination block.

FIG. 21 illustrates an instance in which N is 4. That is, fifth, tenth, . . . word lines are the boundary word lines.

Specifically, the memory controller 4 first executes the TLC program operation that is the first-step program operation on the storage position (0, 0). The memory controller 4 executes the TLC program operation that is the first-step program operation on the storage position (1, 0). Then, the memory controller 4 executes the fine program operation that is the second-step program operation on the storage position (0, 0). That is, in response to completion of the TLC program operation on the memory cell belonging to the same string unit and connected to a subsequent word line, the memory controller 4 executes the fine program operation. The fine program operation executed on the storage position (0, 0) can be executed using the EDL as in the fine program operation in the TLC-fine program operation described with reference to FIG. 20.

From execution of the TLC program operation on the storage position (0, 0) until execution of the fine program operation on the storage position (0, 0), the memory cells on which the first-step program operation is executed are only the storage positions (0, 0) and (1, 0). 3-bit data is written in both memory cells by the TLC program operation. Therefore, the memory controller 4 is required to store data to be additionally written into each of the two storage positions. That is, a buffer that stores data to be written into each of two storage positions is required on the memory controller 4, in which the data corresponds to 2×1 pages.

Thereafter, the memory controller 4 executes the TLC program operation that is the first-step program operation on the storage position (2, 0). The memory controller 4 executes the fine program operation that is the second-step program operation on the storage position (1, 0).

The memory controller 4 executes the TLC program operation that is the first-step program operation on the storage position (3, 0). The memory controller 4 executes the fine program operation that is the second-step program operation on the storage position (2, 0).

The memory controller 4 executes the TLC program operation that is the first-step program operation on the storage position (4, 0) connected to the word line WL4 that is the boundary word line. The memory controller 4 executes the fine program operation that is the second-step program operation on the storage position (3, 0).

In response to completion of the fine program operation on the storage position (3, 0), the memory controller 4 changes the writing destination string unit to the string unit SU1. Then, the memory controller 4 executes the TLC program operation that is the first-step program operation on the storage position (0, 1).

Thereafter, the program operation progresses, and when the TLC program operation on the storage position (4, 4) and the fine program operation on the storage position (3, 4) are completed, the memory controller 4 executes the TLC program operation that is the first-step program operation on the storage position (5, 0) connected to the word line WL5 subsequent to the word line WL4 that is the boundary word line. The memory controller 4 executes the fine program operation that is the second-step program operation on the storage position (4, 0) connected to the word line WL4 that is the boundary word line.

At a timing at which the fine program operation is executed on the storage position (4, 0), the memory cells on which only the first-step program operation is executed and the fine program operation is not yet executed are the storage positions (4, 0), (5, 0), (4, 1), (4, 2), (4, 3), and (4, 4). All of the six storage positions are memory cells in which 3-bit data is written by the TLC program operation. That is, in the memory controller 4, a buffer that stores data to be written into each memory cell is required, in which the data corresponds to 6×1 pages. Therefore, the required size of the buffer and a capacity required for the capacitor 62 can be further reduced than in the first and third comparative examples.

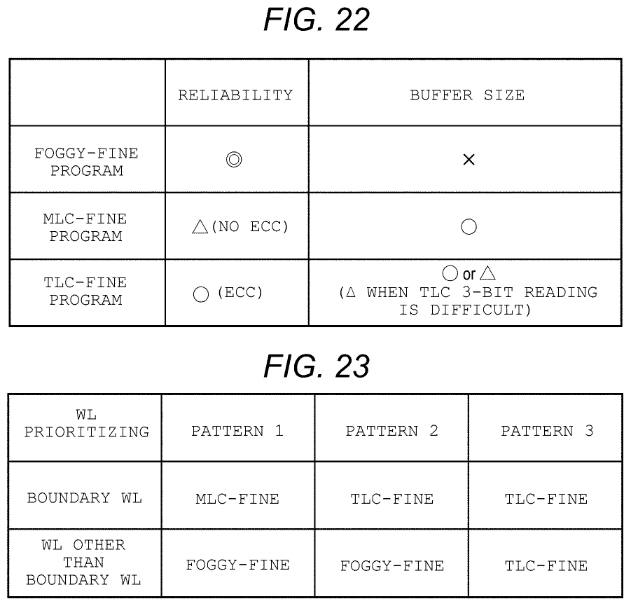

Next, reliability and a buffer size in the three types of 2-step writing schemes will be described. FIG. 22 is a diagram illustrating the three types of 2-step writing schemes according to the embodiment.

The memory controller 4 instructs the NAND flash memory 5 to execute the foggy-fine program operation, the MLC-fine program operation, and the TLC-fine program operation as the 2-step write operation.

When the foggy-fine program operation is executed, reliability of data is high. However, when the foggy-fine program operation is executed, a buffer that has a large size is required for the memory controller 4.

When the MLC-fine program operation is executed, the reliability of data is not very high. However, when the MLC-fine program operation is executed, the required buffer size can be reduced for the memory controller 4.

When the TLC-fine program operation is executed, the reliability of data is higher than when the MLC-fine program operation is executed. This is because the ECC circuit 45 is required to execute error correction when the TLC-fine program operation is executed. Since error correction is executed in the 2-step writing, the reliability of data is ensured. Meanwhile, when the TLC-fine program operation is executed, the buffer size required for the memory controller 4 can be reduced. When it is difficult to read data written by the TLC program operation that is the first-step program operation, a required buffer size is large. In any case, the required buffer size can be further reduced than the case of the foggy-fine program operation.

Next, a combination of the program operations using the three types of writing schemes will be described. FIG. 23 is a diagram illustrating three types of writing patterns according to the embodiment.

The memory system 3 according to the embodiment designates writing destination memory cells in word line WL-major order. When the writing destination memory cells are determined in word line-major order, a period from execution of the first-step program operation until execution of the second-step program operation is longer in the memory cells connected to the boundary word lines than other memory cells. Therefore, a writing scheme for a program operation executed on the memory cells connected to the boundary word lines preferably has a more significant effect of reducing the buffer size.

For a program operation on the memory cells connected to the word lines other than the boundary word lines, reliability of data is preferably ensured.

Therefore, the MLC-fine program operation or the TLC-fine program operation is executed as the program operation on the memory cells connected to the boundary word lines. The foggy-fine program operation or the TLC-fine program operation is executed as the program operation on the memory cells connected to the word lines other than the boundary word lines.

Therefore, as Pattern 1, the memory controller 4 executes the MLC-fine program operation on the memory cells connected to the boundary word lines and executes the foggy-fine program operation on the memory cells connected to the word lines other than the boundary word lines. An example in which Pattern 1 is used is the first example of the writing order described with reference to FIG. 19.

As Pattern 2, the memory controller 4 executes the TLC-fine program operation on the memory cell connected to the boundary word lines and executes the foggy-fine program operation on the memory cells connected to the word lines other than the boundary word lines. An example in which Pattern 2 is used is the second example of the writing order described with reference to FIG. 20.

As Pattern 3, the memory controller 4 executes the TLC-fine program operation on the memory cell connected to the boundary word lines and executes the TLC-fine program operation on the memory cells connected to the word lines other than the boundary word lines. An example in which Pattern 3 is used is the third example of the writing order described with reference to FIG. 21.

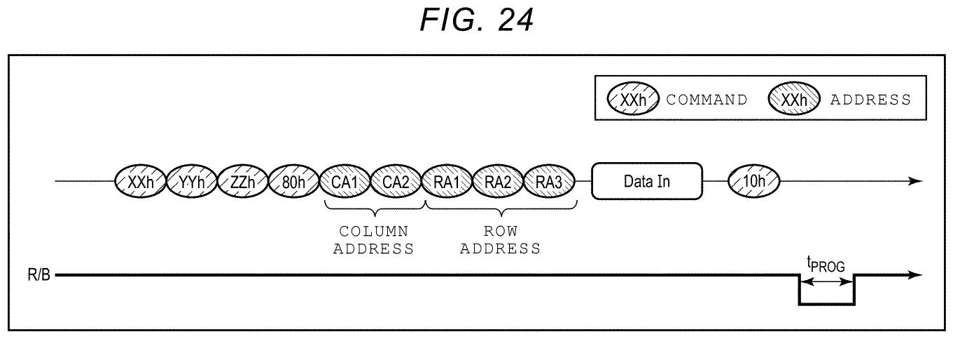

Next, a command sequence transmitted from the memory controller 4 to the NAND flash memory 5 will be described. FIG. 24 is a diagram illustrating an example of a command sequence used in a data write process of the memory system according to the embodiment.

In FIG. 24, the memory controller 4 transmits a command sequence including commands, addresses, and data to the NAND flash memory 5.

The commands include XXh, YYh, and ZZh. In FIGS. 24, 80h is an end position of the commands and indicates a start position of the addresses. In FIGS. 24, 10h indicates an end of the command sequence.

XXh is a command for selecting a writing scheme. XXh indicates any of the foggy-fine program operation, the MLC-fine program operation, or the TLC-fine program operation.

YYh is a command for selecting a step in a program operation. YYh indicates any of the first-step program operation or the second-step program operation.

ZZh is a command for selecting a writing destination page. ZZh indicates any of the top page, the upper page, the middle page, or the lower page.

The addresses include column addresses and row addresses. The column addresses and the row addresses are addresses for designating writing destination memory cells.

t_{PROG} indicates a time in which a program operation is executed. During t_{PROG}, the NAND flash memory 5 enters a busy state.

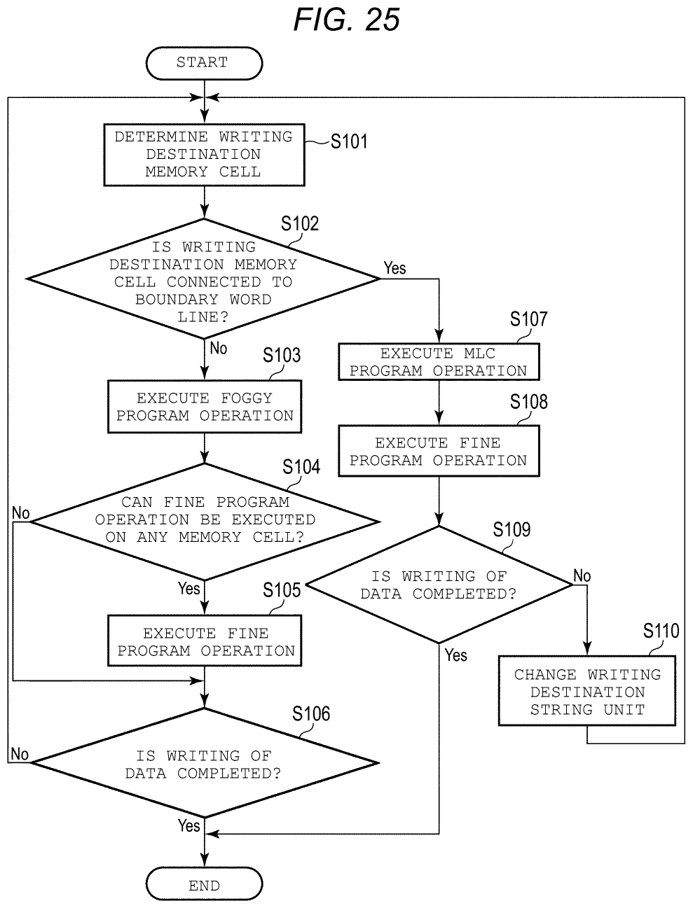

Next, a procedure of a data write process during use of Pattern 1 executed by the memory controller 4 will be described. FIG. 25 is a flowchart illustrating a procedure of a data write process executed in the memory system 3 during use of Pattern 1 according to the embodiment.

As Pattern 1 is used, it is assumed that the memory controller 4 instructs the NAND flash memory 5 to execute the MLC-fine program operation on the memory cells connected to the boundary word lines and to execute the foggy-fine program operation on the memory cells connected to the word lines other than the boundary word lines.

First, the memory controller 4 determines writing destination memory cells (step S101). The memory controller 4 determines the memory cells in a writing destination block based on a writing order determined in advance.

The memory controller 4 determines whether the writing destination memory cells determined in S101 are memory cells connected to the boundary word line (step S102).

When the writing destination memory cells are not connected to the boundary word line (No in S102), the memory controller 4 executes the foggy program operation on the writing destination memory cells (step S103). The memory controller 4 transmits a command sequence including addresses for designating the writing destination memory cells and a command for designating the foggy program operation to the NAND flash memory 5.

The memory controller 4 determines whether the fine program operation can be executed on any memory cells due to the foggy program operation being executed in S103 (step S104). The fine program operation can be executed on memory cells belonging to the same string unit and connected to a word line immediately before a word line to which the memory cells subjected to the foggy program operation in S103 are connected. For example, when the word line to which the memory cells subjected to the foggy program operation in S103 are connected is the word line subsequent to the boundary word line, the fine program operation can be executed on the memory cells connected to the boundary word line.

When the fine program operation can be executed on any memory cells (Yes in S104), the memory controller 4 executes the fine program operation on the memory cells on which the fine program operation can be executed in S104 (step S105). Accordingly, the writing destination memory cells store readable 4-bit data.

When the fine program operation cannot be executed on any memory cells (No in S104), the memory controller 4 skips the procedure of S105.

The memory controller 4 determines whether the data write process is completed (step S106).

When the data write process is completed (Yes in S106), the memory controller 4 ends the data write process.

When the data write process is not completed (No in S106), the memory controller 4 returns to S101 and determines subsequent writing destination memory cells.

When the writing destination memory cells are connected to the boundary word line (Yes in S102), the memory controller 4 executes the MLC program operation on the writing destination memory cells determined in S101 (step S107).

The memory controller 4 executes the fine program operation on the memory cells on which the fine program operation can be executed due to the MLC program operation being executed in S107 (step S108). For example, the fine program operation can be executed on the memory cells belonging to the same string unit and connected to the word line immediately before the word line to which the memory cells subjected to the MLC program operation in S107 are connected.

The memory controller 4 determines whether the data write process is completed (step S109).

When the data write process is completed (Yes in S109), the memory controller 4 ends the data write process.

When the data write process is not completed (No in S109), the memory controller 4 changes the writing destination string unit (step S110). The memory controller 4 determines a string unit subsequent to the string unit to which the current writing destination memory cells belong as a writing destination string unit. Then, the memory controller 4 returns to S101 and determines subsequent writing destination memory cells.

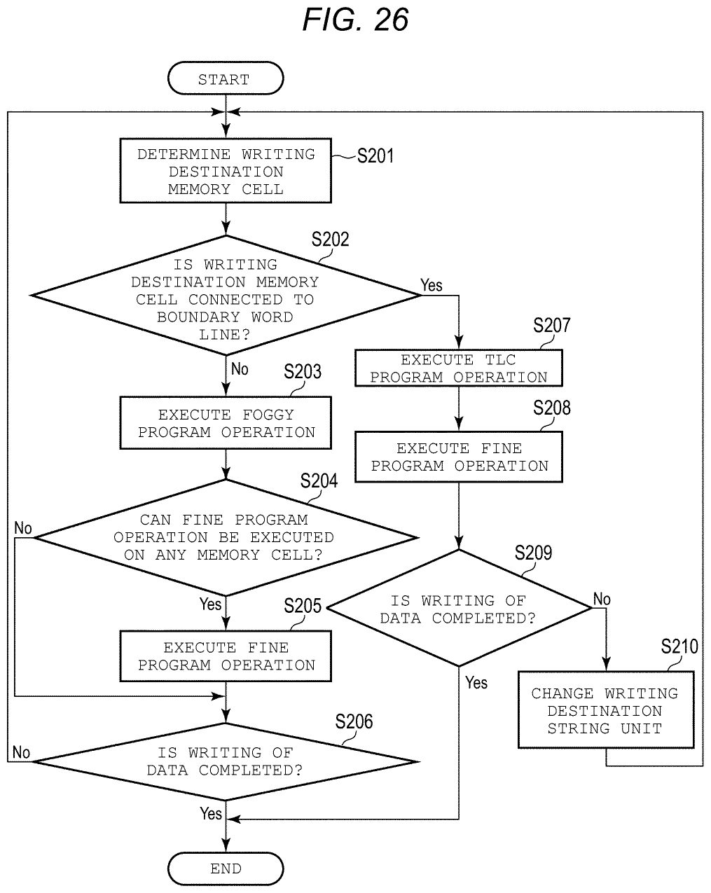

Next, a procedure of a data write process during use of Pattern 2 executed by the memory controller 4 will be described. FIG. 26 is a flowchart illustrating a procedure of a data write process executed in the memory system 3 during use of Pattern 2 according to the embodiment.

As Pattern 2 is used, it is assumed that the memory controller 4 instructs the NAND flash memory 5 to execute the TLC-fine program operation on the memory cells connected to the boundary word lines and to execute the foggy-fine program operation on the memory cells connected to the word lines other than the boundary word lines.

First, the memory controller 4 determines writing destination memory cells (step S201). The memory controller 4 determines the memory cells in a writing destination block based on a writing order determined in advance.

The memory controller 4 determines whether the writing destination memory cells determined in S201 are memory cells connected to the boundary word line (step S202).

When the writing destination memory cells are not connected to the boundary word line (No in S202), the memory controller 4 executes the foggy program operation on the writing destination memory cells (step S203). The memory controller 4 transmits a command sequence including addresses for designating the writing destination memory cells and a command for designating the foggy program operation to the NAND flash memory 5. Note that, when Pattern 3 is used instead of Pattern 2, the memory controller 4 executes the TLC program operation on the writing destination memory cells.

The memory controller 4 determines whether the fine program operation can be executed on any memory cells due to the foggy program operation being executed in S203 (step S204). The fine program operation can be executed on memory cells belonging to the same string unit and connected to a word line immediately before a word line to which the memory cells subjected to the foggy program operation in S204 are connected. For example, when the word line to which the memory cells subjected to the foggy program operation in S203 are connected is the word line subsequent to the boundary word line, the fine program operation can be executed on the memory cells connected to the boundary word line.

When the fine program operation can be executed on any memory cells (Yes in S204), the memory controller 4 executes the fine program operation on the memory cells on which the fine program operation can be executed in S204 (step S205). Accordingly, the writing destination memory cells store readable 4-bit data.

When the fine program operation cannot be executed on any memory cells (No in S204), the memory controller 4 skips the procedure of S205.

The memory controller 4 determines whether the data write process is completed (step S206).

When the data write process is completed (Yes in S206), the memory controller 4 ends the data write process.

When the data write process is not completed (No in S206), the memory controller 4 returns to S201 and determines subsequent writing destination memory cells.

When the writing destination memory cells are connected to the boundary word line (Yes in S202), the memory controller 4 executes the TCL program operation on the writing destination memory cells determined in S201 (step S207).

The memory controller 4 executes the fine program operation on the memory cells on which the fine program operation can be executed due to the TLC program operation being executed in S207 (step S208). For example, the fine program operation can be executed on the memory cells belonging to the same string unit and connected to the word line immediately before the word line to which the memory cells subjected to the TLC program operation in S207 are connected.

The memory controller 4 determines whether the data write process is completed (step S209).

When the data write process is completed (Yes in S209), the memory controller 4 ends the data write process.

When the data write process is not completed (No in S209), the memory controller 4 changes the writing destination string unit (step S210). The memory controller 4 determines a string unit subsequent to the string unit to which the current writing destination memory cells belong as a writing destination string unit. Then, the memory controller 4 returns to S201 and determines subsequent writing destination memory cells.

As described above, in the memory system 3 according to the embodiment, the memory controller 4 determines the writing destination memory cells in word line-major order in the data write process on the writing destination block. The memory controller 4 executes the MLC-fine program operation that is the 2-step write operation on the memory cells connected to the boundary word lines. The memory controller 4 may execute the TLC-fine program operation as the 2-step write operation instead of the MLC-fine program operation on the memory cells connected to the boundary word lines.

The memory controller 4 can shorten a period for which the memory controller 4 is required to store data to be written into the memory cells connected to the word lines other than the boundary word lines by determining the writing destination memory cells in word line-major order.

The memory controller 4 can reduce the size of data required to be stored on the memory controller 4 by executing the MLC-fine program operation or the TLC-fine program operation on the memory cells connected to the boundary word lines.

The memory controller 4 can write 4-bit data in the end even on the memory cells connected to the boundary word lines by executing the MLC-fine program operation or the TLC-fine program operation. Therefore, it is possible to prevent a loss of maximum capacity from occurring in the memory system 3 according to the embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory system comprising:
a nonvolatile memory including a first array of memory cells connected to a first group of word lines, a second array of memory cells connected to a second group of word lines, and a third array of memory cells connected to a boundary word line extending between the first group of word lines and the second group of word lines; and
a memory controller configured to:
perform a two-step program operation of a first type to write multi-bit data with respect to each memory cell in the first and second arrays, the two-step program operations of the first type including a first program operation to set a threshold voltage of the memory cell to be in one of a first plurality of threshold voltage ranges with overlaps thereamong, and then a second program operation to set the threshold voltage to be in one of a second plurality of threshold voltage ranges without overlap thereamong; and
perform a two-step program operation of a second type to write multi-bit data with respect to each memory cell in the third array, the two-step program operations of the second type including a third program operation to set the threshold voltage to be in one of a third plurality of threshold voltage ranges corresponding to partial, but not entire, bits of the multi-bit data, and then a fourth program operation to set the threshold voltage to be in one of a fourth plurality of threshold voltage ranges corresponding to the entire bits of the multi-bit data.

2. The memory system according to claim 1, wherein
the multi-bit data written by the two-step program operation of the first type and the second type is data of four or more bits, and
the partial bits of data programmed through the third program operation are two bits.

3. The memory system according to claim 1, wherein
the multi-bit data written by the two-step program operation of the first type and the second type is data of four or more bits, and
the partial bits of data programmed through the third program operation are three bits.

4. The memory system according to claim 1, wherein the number of threshold voltage ranges in the first plurality is the same as the number of threshold voltage ranges in the second plurality.

5. The memory system according to claim 1, wherein
the number of word lines included in the first group is four or more, and
the number of word lines included in the second group is four or more.

6. The memory system according to claim 1, wherein the memory controller is configured to perform the second program operation with respect to a first memory cell in the first array connected to a first word line, after the first program operation with respect to a second memory cell that is adjacent to the first memory cell and connected to a second word line adjacent to the first word line.

7. The memory system according to claim 6, wherein the memory controller is configured to perform the first program operation with respect to a third memory cell in the first array that is adjacent to the second memory cell and connected to a third word line adjacent to the second word line, after the second program operation with respect to the first memory cell.

8. The memory system according to claim 7, wherein the memory controller is configured to perform the second program operation with respect to a fourth memory cell that is in the first array and adjacent to a fifth memory cell in the third array, after the third program operation with respect to the fifth memory cell.

9. The memory system according to claim 8, wherein the memory controller is configured to perform the fourth program operation with respect to the fifth memory cell, after the first program operation with respect to a sixth memory cell that is in the second array and adjacent to the fifth memory cell.

10. The memory system according to claim 8, wherein the memory controller is configured to perform the fourth program operation with respect to each memory cell in the third array, after the second program operation with respect to all memory cells in the first array.

11. The memory system according to claim 1, wherein
the first array of memory cells includes a first memory cell string connected to a first bit line and a second memory cell strings connected to a second bit line adjacent to the first bit line, and
the memory controller is configured to perform the first program operation with respect to each memory cell in the second memory cell string, after the second program operation with respect to each memory cell in the first memory cell string.

12. A memory system comprising:
a nonvolatile memory including a first array of memory cells connected to a first group of word lines, a second array of memory cells connected to a second group of word lines, and a third array of memory cells connected to a boundary word line extending between the first group of word lines and the second group of word lines; and
a memory controller configured to perform a two-step program operation to write multi-bit data with respect to each memory cell in the first, second, and third arrays, the two-step program operations including a first program operation to set a threshold voltage of the memory cell to be in one of a first plurality of threshold voltage ranges corresponding to partial, but not entire, bits of the multi-bit data, and then a second program operation to set the threshold voltage to be in one of a second plurality of threshold voltage ranges corresponding to the entire bits of the multi-bit data, wherein
the memory controller is configured to perform the second program operation with respect to each memory cell in the third array, after the second program operation with respect to all memory cells in the first array.

13. The memory system according to claim 12, wherein
the multi-bit data written by the two-step program operation of the first type and the second type is data of four or more bits, and
the partial bits of data programmed through the third program operation are two bits.

14. The memory system according to claim 12, wherein
the multi-bit data written by the two-step program operation of the first type and the second type is data of four or more bits, and
the partial bits of data programmed through the third program operation are three bits.

15. The memory system according to claim 12, wherein the memory controller is configured to perform the second program operation with respect to a first memory cell in the first array connected to a first word line, after the first program operation with respect to a second memory cell that is adjacent to the first memory cell and connected to a second word line adjacent to the first word line.

16. The memory system according to claim 15, wherein the memory controller is configured to perform the first program operation with respect to a third memory cell in the first array that is adjacent to the second memory cell and connected to a third word line adjacent to the second word line, after the second program operation with respect to the first memory cell.

17. The memory system according to claim 16, wherein the memory controller is configured to perform the second program operation with respect to a fourth memory cell that is in the first array and adjacent to a fifth memory cell in the third array, after the third program operation with respect to the fifth memory cell.

18. The memory system according to claim 17, wherein the memory controller is configured to perform the second program operation with respect to the fifth memory cell, after the first program operation with respect to a sixth memory cell that is in the second array and adjacent to the fifth memory cell.

19. The memory system according to claim 12, wherein
the first array of memory cells includes a first memory cell string connected to a first bit line and a second memory cell strings connected to a second bit line adjacent to the first bit line, and
the memory controller is configured to perform the first program operation with respect to each memory cell in the second memory cell string, after the second program operation with respect to each memory cell in the first memory cell string.

20. A method for writing data into a nonvolatile memory including a first array of memory cells connected to a first group of word lines, a second array of memory cells connected to a second group of word lines, and a third array of memory cells connected to a boundary word line extending between the first group of word lines and the second group of word lines, the method comprising:
performing a two-step program operation of a first type to write multi-bit data with respect to each memory cell in the first and second arrays, the two-step program operations of the first type including a first program operation to set a threshold voltage of the memory cell to be in one of a first plurality of threshold voltage ranges with overlaps thereamong, and then a second program operation to set the threshold voltage to be in one of a second plurality of threshold voltage ranges without overlap thereamong; and
performing a two-step program operation of a second type to write multi-bit data with respect to each memory cell in the third array, the two-step program operations of the second type including a third program operation to set the threshold voltage to be in one of a third plurality of threshold voltage ranges corresponding to partial, but not entire, bits of the multi-bit data, and then a fourth program operation to set the threshold voltage to be in one of a fourth plurality of threshold voltage ranges corresponding to the entire bits of the multi-bit data.
